(19) United States
(12) Patent Application Publication
(10) Pub. No.: US 2026/0015369 A1
(43) Pub. Date: Jan. 15, 2026

(54) PEROVSKITE SYSTEM INCLUDING ANILINIUM-BASED LIGANDS AND RELATED PEROVSKITE SOLAR CELL

(71) Applicant: THE GOVERNING COUNCIL OF THE UNIVERSITY OF TORONTO, Toronto (CA)

(72) Inventors: So Min PARK, Toronto (CA); Mingyang WEI, Toronto (CA); Edward H. SARGENT, Toronto (CA)

(73) Assignee: THE GOVERNING COUNCIL OF THE UNIVERSITY OF TORONTO, Toronto (CA)

(21) Appl. No.: 19/268,024

(22) Filed: Jul. 14, 2025

Related U.S. Application Data
(60) Provisional application No. 63/670,527, filed on Jul. 12, 2024.

(30) Foreign Application Priority Data
Jul. 12, 2024 (CA) 3248416

(51) Int. Cl. C07F 7/24; H10K 30/40

(52) U.S. Cl. CPC C07F 7/24; H10K 30/40

(57) ABSTRACT

The present disclosure relates to a perovskite system comprising a perovskite film including perovskites having a three-dimensional heterostructure of formula ABX₃ characterized by a tetragonal perovskite surface. A comprises at least one of methylammonium, formamidinium, cesium, or guanidinium. B is Pb or Sn. X comprises at least one of I, Br, or Cl. The perovskite system further comprises an interfacial capping layer including anilinium-based surface-capping ligands, the ligands being distributed at the tetragonal perovskite surface of the perovskite film and non-reactive with the perovskites, as determined by time-of-flight secondary ion mass spectrometry. Also described are methods of preparing the perovskite system, and solar cells or modules comprising the perovskite system.

### GOVERNMENT SPONSORSHIP

This invention was made with government support under grant no. N00014-20-1-2572 awarded by the US Department of the Navy, Office of Naval Research. The government has certain rights in the invention.

### TECHNICAL FIELD

The present invention generally relates to perovskite solar cells (PSCs), and more particularly to a perovskite system including an interfacial capping layer comprising surface-capping ligands distributed at a tetragonal perovskite surface of a perovskite film.

### BACKGROUND

Metal-halide perovskite solar cells (PSCs) are emerging photovoltaic (PV) technologies that hold promise in terawatt-scale deployment. They unite high power-conversion efficiencies (certified PCEs up to 25.7%) with low-cost solution processing that uses abundant materials. To compete with crystalline silicon (c-Si) solar cells and to be applied with c-Si in tan-dem cells, PSCs need improved evidence of bankability, such as operating stability at elevated temperatures in accelerated aging.

Interfaces, which have high defect densities, low barriers to ion transfer and are susceptible to moisture- and oxygen-induced degradation, can provide pathways for energy loss and degradation in PSCs. In record-efficiency PSCs, interfaces have been passivated by using two- and three-dimensional (2D/3D) hybrid structures, where a thin layer of Ruddlesden-Popper 2D perovskites terminates the 3D-perovskite surface. These 2D/3D structures are constructed by exposing perovskite surfaces to a solution containing ammonium ligands, during which the 3D lattice is fragmented into 2D layers.

Stability of 2D overlayers under stress have been studied. Some studies have indicated limited stability of the 2D/3D interface under thermal stress, but improvements have been achieved with incorporation of 3-fluorophenethylammonium (3FPEA) intercalation showing 500-hour operating stability under conditions of 65° C., 50% relative humidity (RH), and maximum power point (MPP) tracking. An oleylammonium-intercalated 2D overlayer was also used and showed promising results in a 1000-hour damp-heat test, although this study was based on silicon PV module IEC 61215:2016 standards (85° C. and 85% RH, dark).

Two types of 2D/3D heterostructures have been reported for ISOS-L-3-stable PSCs: 3FPEA-intercalated 2D/3D perovskites and all-inorganic heterostructures. For all-inorganic PSCs, a T₈₅ reached 4000 hours at 85° C., but with further room for progress in PCE (≤17% when measured at 85° C.). 3FPEA-based PSCs have achieved PCEs exceeding 23% at room temperature, but stable operation over 500 hours was limited to 65° C.

Given these promising performance and stability improvements, the field continues to pursue ever-higher durability targets. There is interest in raising the standard to 85° C. ISOS-L-3 (MPP tracking at 85° C. and 50% RH). However, the reactivity of ammonium ligands with 3D perovskites may lead to further penetration into the bulk perovskite film and may contribute to deterioration in device performance under these very demanding stress conditions.

Perovskite solar cells (PSCs) consisting of interfacial two- and three-dimensional heterostructures that incorporate ammonium ligand intercalation have enabled rapid progress toward the goal of uniting performance with stability. However, as the field continues to seek ever-higher durability, additional tools that avoid progressive ligand intercalation are needed to minimize degradation at high temperatures.

### SUMMARY

There is proposed a PSC including ammonium ligands that are nonreactive with the bulk of perovskites and having a ligand molecular structure tailored to ensure non-reactivity thereof with perovskites. For example, the ammonium ligand can be anilinium or derivatives thereof, such as fluorinated anilinium that was found to further offer interfacial passivation and simultaneously minimize reactivity with perovskites. Using tailored ammonium ligand, an inverted-structure PSC has been found to have a certified quasi-steady-state power-conversion efficiency of 24.09%. In an encapsulated device operating at 85° C. and 50% relative humidity, a 1560-hour T₈₅ at maximum power point under 1-sun illumination was achieved.

In one aspect, there is provided a perovskite system comprising:
a perovskite film comprising perovskites having a three-dimensional heterostructure ABX₃ being characterized by a tetragonal perovskite surface,
   wherein A comprises at least one of methylammonium (MA), formamidinium (FA), cesium (Cs) and guanidium (GUA),
   wherein B is Pb or Sn, and
   wherein X comprises at least one of I, Br or Cl; and
an interfacial capping layer comprising surface-capping ligands being anilinium (An)-based ligands, wherein the surface-capping ligands are distributed at the tetragonal perovskite surface of the perovskite film and are non-reactive with the perovskites, as measured by time-of-flight secondary ion mass spectrometry (TOF-SIMS).

In some embodiments, the An-based ligand can be anilinium.

In some embodiments, the An-based ligand can be an alkyl anilinium.

In some embodiments, the An-based ligand can be tert-butyl-substituted 3,5-di-tert-butylanilinium, 3-tert-butylanilinium, 4-tert-butylanilinium, or any mixtures thereof.

In some embodiments, the surface-capping ligand can be a surface-passivating ligand being a fluorinated anilinium ligand, thereby forming the interfacial capping layer being an interfacial passivating layer.

In another aspect, there is provided a perovskite system comprising:
a perovskite film comprising perovskites having a three-dimensional heterostructure ABX₃ being characterized by a tetragonal perovskite surface,
   wherein A comprises at least one of methylammonium (MA), formamidinium (FA), cesium (Cs) and guanidium (GUA),
   wherein B is Pb or Sn, and
   wherein X comprises at least one of I, Br or Cl; and
an interfacial passivating layer comprising surface-passivating ligands being fluorinated anilinium (An) ligands, wherein the surface-passivating ligands are distributed at the tetragonal perovskite surface of the perovskite film and are non-reactive with the perovskites, as measured by time-of-flight secondary ion mass spectrometry (TOF-SIMS).

In some embodiments, the fluorinated anilinium ligand can be 2-fluoroanilinium (2FAn), 3-fluoroanilinium (3FAn), 4-fluoroanilinium (4FAn), 2,6-difluoroanilinium (26FAn), 3,4,5-trifluoroanilinium (345FAn), 2,3,4,5,6-pentafluoroanilinium (23456FAn), or any mixtures thereof.

In some embodiments, a C—N/FA N ratio of the anilinium-based ligand in the perovskite solar cell system can be of at most 0.1, optionally of at most 0.05, measured by angle-resolved x-ray photoelectron spectroscopy (AR-XPS).

In some embodiments, the An-based ligand has a steric effect index (STEI) can be of at least 2, at least 2.1, at least 2.2, at least 2.3 or at least 2.4 as calculated by density-functional theory (DFT) calculations.

In some embodiments, the An-based ligand can have a solubility in isopropanol between 0.5 and 5 mg m⁻¹, as determined by standard gravimetric analysis.

In some embodiments, the interfacial passivating layer has a thickness of at most 10 nm as measured by TOF-SIMS.

In some embodiments, A can consist of MA. Optionally, ABX₃ can be MAPbI₃.

In some embodiments, A can have the formula CsₓMA_{y}FA_{i-x-y}, wherein x is in a range from 0<x<1, wherein y is in a range from 0<y<1, wherein i is in a range from 0<i<1, and wherein x+y<1. Optionally, ABX₃ can be CS_{0.05}MA_{0.05}FA_{0.9}Pb(I_{0.95}Br_{0.05})₃. Further optionally, ABX₃ can be CS_{0.05}MA_{0.15}FA_{0.8}PbI₃.

In another aspect, there is provided a solar cell or module comprising at least one perovskite system as defined herein.

In some embodiments, the solar cell or module further comprises a hole transport layer onto which the perovskite film is deposited, and the hole-transport layer can be a self-assembled monolayer 2PACz, 2PACz derivatives, a polymeric hole conductor poly(triaryl amine) (PTAA), poly(3,4-ethylenedioxythiophene) polystyrene sulfonate (PEDOT), or a p-type inorganic semiconductor, optionally being nickel oxide (NiOₓ).

In some embodiments, the solar cell or module comprises a substrate onto which the hole-transport layer is deposited, and the substrate can be Fluorine-doped Tin Oxide (FTO) glass or an Indium Tin Oxide (ITO) glass.

In some embodiments, the solar cell or module further comprises an electron transport layer being deposited on the perovskite system, and the electron transport layer can be a thermally evaporated C₆₀/bathocuproine (BCP) bilayer, solution-processed [6,6]-phenyl-C61-butyric acid methyl ester (PCBM)/BCP bilayer, or C₆₀/ALD-SnO₂ bilayer.

In another aspect, there is provided a method for preparing a perovskite system as defined herein. The method includes providing a solution comprising the anilinium-based ligand and a solvent; coating the perovskite film with the solution during a processing time of at least 5 seconds for distributing the anilinium-based ligands onto the tetragonal perovskite surface and produce a surface-treated perovskite film; and annealing the surface-treated perovskite film to form the perovskite system.

In some embodiments, the processing time can be between 5 seconds and 30 seconds.

In some embodiments, the solvent can be isopropanol, chlorobenzene, chloroform, toluene, or any mixtures thereof.

In some embodiments, the solution can have a concentration in the anilinium-based ligand between 0.2 and 2 mg/mL.

In some embodiments, the coating can be performed by spin-coating, blade-coating, or slot-die coating.

In some embodiments, the annealing can be performed at a temperature between 60° C. and 120° C. for a second processing time between 1 min and 10 min.

While the invention will be described in conjunction with example embodiments, it will be understood that it is not intended to limit the scope of the invention to such embodiments. On the contrary, it is intended to cover all alternatives, modifications and equivalents as may be included as defined by the present description. The objects, advantages and other features of the present invention will become more apparent and be better understood upon reading of the following non-restrictive description of the invention, given with reference to the accompanying drawings.

### BRIEF DESCRIPTION OF THE DRAWINGS

Implementations of the perovskite system and related solar cell are represented in and will be further understood in connection with the following figures.

FIG. 1 shows angle-resolved x-ray photoelectron spectroscopy (AR-XPS) characterization of ammonium ligand penetration and includes (1A) Chemical structures of tested surface-passivating ligands being ammonium ligands; (1B) Experimental setup for AR-XPS characterization with an electron takeoff angle a being defined as the angle between a normal of a sample substrate and an analyzer; (1C) Schematic indicating the relation between a and a photoelectron probing depth, d; and (1D and 1E) C—N to FA N ratios at electron takeoff angles of 0°, 45°, and 75° for the control (untreated) and ammonium ligand-treated perovskite films. The results show reduced bulk and surface existence for An and An derivatives.

FIG. 2 shows phase transformation of perovskite films and includes (2A to 2C) Pseudocolor representation of the transient reflectance spectra, DR/R, for phenethylammonium (PEA)-treated (2A), for a An-treated (2B), and for 345FAn-treated (2C) perovskite films, respectively, demonstrating that with n=1, n=2, n=3 2D perovskites (n₁, n₂, and n₃) appear in the film after PEA passivation; (2D to 2F) GIWAXS image for perovskite films of PEA (2D), An (2E), and 345FAn (2F) passivation, respectively, wherein the color bar shows the diffraction intensity collected from the GIWAXS detector, q_{xy} and q_{z} represent in-plane and near out-of-plane scattering vectors, respectively, and wherein for n=2 2D perovskite (n₂) and PbI₂-related diffraction peaks are observed in the PEA- and An-treated films, respectively, while (100) refers to the (100) diffraction peak of 3D perovskites.

FIG. 3 shows DFT studies and includes (3A) Schematic depiction of the model of ammonium ligand and perovskite interactions; (3B) Models used in DFT calculations to calculate the binding energy (Eb) of adjacent 2D perovskite fragments; (3C) Eb values for seven ammonium ligands substituted into MAPbI₃ perovskite slabs; (3D) Models used to calculate the interaction energy (Eᵢₙₜ) of ammonium ligands with the MAPbI₃ perovskite surface; and (3E) Eᵢₙₜ values of four ammonium ligands with the perovskite surface.

FIG. 4 shows thermal stability of perovskite films and includes (4A and 4B) Pseudocolor representation of the transient reflectance spectra for PEA-treated perovskite films before (4A) and after (4B) thermal aging at 85° C. for 2 hours, demonstrating that 2D perovskites were decomposed into PbI₂ after thermal aging; (4C) time-of-flight secondary ion mass spectrometry (TOF-SIMS) showing distribution of PEA⁺ and An⁺ in fresh and aged (at 85° C. for 2 hours) perovskite films; (4D) PL spectra of perovskite thin films under thermal annealing at 85° C., wherein films were kept on a hot plate at 85° C. in the N2-filled glovebox and measured every 24 hours in ambient air; (4E) graph of changes in PL intensity for different annealing times, wherein data are presented as mean values±standard deviation for three films (+control) that were measured under each condition.

FIG. 5 shows photovoltaic performance of PSCs with interface engineering as defined herein and includes (5A) graph of PCE (%) for control (8 devices) versus ammonium ligand-treated (16 devices for each PEA-treated, An-treated and 345FAn-treated type) PSCs; (5B) EQE curves of the control and ammonium ligand-treated PSC devices; (5C) QSS current density-voltage (J-V) curve of one representative 345FAn device certified at NREL, with (Inset) PV parameters of the device; (5D) graph of PCE evolution of PEA and 345FAn devices as a function of solution exposure time (8 devices for each condition) with data being presented as mean values±standard deviation and (Inset) schematic illustration of a solution exposure process for interface engineering; (5E) graph of MPP tracking of encapsulated control, PEA, and 345FAn devices performed using ITO substrates at 85° C. with an RH of ˜50% under 0.8-sun illumination and (5F and 5G) PCE (5F), current density (Jₘₚₚ), and voltage (Vₘₚₚ) (5G) at the MPP of the encapsulated 345FAn device determined using a Fluorine-doped Tin Oxide (FTO) substrate under 1-sun illumination at 85° C. and ˜50% RH.

FIG. 6 includes graphs a to e of AR-XPS N 1 s region of perovskite films as a function of the electron take-off angles 0°, 45°, and 75°: PEA (a), 3FPEA (b), BA (c), OA (d), and DA (e) treated films, with the peak at around 401.5 eV fits the C—N bond and the peak at around 399.8 eV to the N from FA.

FIG. 7 includes graphs a to f of AR-XPS N 1 s region of An and An derivative treated perovskite films as a function of the electron take-off angles 0°, 45°, and 75°: a-f, control (a), An (b), 4FAn (c), 26FAn (d), 345FAn (e), and 35tbuAn (f) treated films, wherein the peak at around 401.5 eV fits the C—N bond and the peak at around 399.8 eV to the N from FA.

FIG. 8 includes graphs a-c of TOF-SIMS results of PEA- (a) and An- (b) treated perovskite films, with An⁺ cation signals being detected near the top film surface, and Both PbI²⁺ and FA⁺ cations displaying a drop in intensities when the sputtering time exceeds 900 seconds, as the sputtering process reaches the bottom region of the perovskite film layer and thus there are fewer perovskite materials available for removal, and (c) showing a comparison of ligand distribution between PEA- and An-treated perovskite films, with FA⁺ cation signals being plotted for the PEA-treated (dotted points) and An-treated (solid points) samples as the reference, and all plots being derived from raw data without normalization.

FIG. 9 includes graphs a to d of AR-XPS F 1 s region of perovskite films at the electron take-off angle of 0°, 45°, and 75°: 4FAn (a), 26FAn (b), and 345FAn (c)-treated films show negligible C—F signals; and (d) showing a C—F peak for 3FPEA-treated perovskites at different electron take-off angles, with the solid peak fits the C—F bond.

FIG. 10 is a graph of TOF-SIMS of 345FAn-treated perovskite films.

FIG. 11 includes graph (a) being a Pseudocolour plot of AR/R as a function of incident photon wavelength and delay time for the control perovskite film; graphs (b) to (d) being TR spectra of the PEA (b), An (c), and 345FAn (d) treated perovskite films at the pump-probe delay time of 410 fs, as a function of the solution exposure time, wherein for n=1, 2, and 3 2D perovskites were found for the PEA-treated films, and their relative proportion to 3D perovskites being increased when the exposure time is prolonged. For An and 345FAn treated films, no 2D phases were detected, irrespective of the exposure time. It is noted that TR spectroscopy is utilized only for examining the phase distribution of quasi-2D perovskites, while photoinactive δ-FAPbI₃ and PbI₂ are detected by GIWAXS.

FIG. 12 is a graph of XRD patterns of mixed An+PbI₂ (top) and 345FAn+PbI₂ (bottom) films, with (001) and (101) diffraction peaks of PbI₂ being observed and no 2D-related diffraction peaks being observed for either film.

FIG. 13 includes graphs (a) to (c) of GIWAXS spectra as a function of incidence angle 0.08°, 0.12°, 0.25°, and 0.5°—cuts near the q_{z} axis of GIWAXS measurements for PEA (a), An (b), and 345FAn (c) treated perovskite films, with n=2 2D perovskites (n2) were observed in the PEA-treated films only at low incidence angles, indicative of the preferable presence of 2D perovskites on the film surface, with PbI₂ being observed in the An-treated films due to surface degradation and 0 indicating the hexagonal perovskite phase.

FIG. 14 includes graphs (a) to (d) of XRD patterns of perovskite films with varying solution exposure times: a, XRD patterns of control perovskite films with the asterisk symbol (*) indicating PbI₂ species; b-d, XRD patterns of 4FAn (b), 26FAn (c), and 345FAn (d) treated perovskite films showing that the generation of PbI₂ during exposure to both pure solvent and An-solution is comparable, which suggests that the decomposition of perovskites is caused by solvents; and showing that films exposed to 26FAn and 345FAn solution exhibited minimal PbI₂ generation, indicating these ammonium ligands can protect perovskites from degradation more efficiently than An.

FIG. 15 includes contact angle images (a) to (f) of control and various ammonium ligand-treated perovskite films being control (a), An- (b), 4Fan- (c), 26FAn- (d), 345FAn- (e), and 35tbuAn- (f) treated perovskite films, with all images being recorded 2 seconds after the DI water drop was placed on the surface.

FIG. 16 shows DFT analysis of MA vacancy formation in various intercalated 2D/3D interfaces, including Computational models 16a used to determine the MA vacancy formation energy in the case of 345FAn intercalation; and graph 16b of MA vacancy formation energies for PEA, An and 345FAn intercalation. Compared to PEA, the removal of MA cations becomes energetically less favorable for An and 345FAn.

FIG. 17 shows Gaussian calculated electrostatic potentials (9) of An and fluorinated An ligands. The right color bar from bottom to top marks the increase of electro positivity. The φmax is the maximum electrostatic potential amplitude of a specific ligand.

FIG. 18 shows AR-XPS N 1 s region of aged perovskite films as a function of the electron take-off angles 0°, 45°, and 75° including graphs 18a and 18b: PEA (a), and 3FPEA (b) treated films measured after 85° C. annealing for 2 h. The peak at around 401.5 eV fits the C—N bond and the peak at around 399.8 eV to the C═N bond. At a 75° electron take-off angle, the C—N signals diminish significantly in comparison to the fresh sample for both films, suggesting decreased surface presence due to ligand penetration.

FIG. 19 shows phase stability of penetrating ammonium ligand-treated perovskite films, and includes graphs 19a to 19d being each a pseudocolor representation of the transient reflectance spectra for ligands 3FPEA (a), alkyl ammoniums butylammonium BA (b), octyl ammonium OA (c), and alkyl ammonium decylammonium DA (d) treated perovskite films before (fresh) and after (aged) thermal aging at 85° C. for 2 h. All 2D phases disappeared from the film surfaces after thermal aging.

FIG. 20 shows phase stability of 345FAn treated films at elevated temperatures including graphs 20a and 20b being each a pseudocolor representation of the transient reflectance spectra for the 345FAn treated perovskite film before (20a) and after (20b) thermal aging at 85° C. for 2 h. No apparent phase change was observed after thermal aging.

FIG. 21 is a cross-sectional SEM image of 345FAn treated inverted PSCs. Scale bar=1 μm.

FIG. 22 shows the performance of control and treated PSCs including graphs 22a to 22d, PV parameters, including PCE (22a), Jsc (22b), Voc (22c), and FF (22d), of control devices (8 devices) and treated PSCs (16 devices for each type).

FIG. 23 shows PV parameters of treated Cs0.05MA0.05FA0.9Pb(I0.95Br0.05)3 devices: including graphs 23a to 23d for PCE (23a), Jsc (23b), Voc (23c), and FF (23d) of 345FAn-treated devices (8 devices). Statistical distribution is represented in box-and-whisker plots (line within the box: median, box limit: 25th and 75th percentiles, whiskers: outliers).

FIG. 24 shows certified results of the inverted PSC with 345FAn passivation.

FIG. 25 shows UPS spectra and energy level schematic including graphs 25a and 25b od secondary electron cut-off region (25a), and valence band onset region (25b) plotted on a relative logarithmic scale of control and ammonium ligand treated films. The x-axis energy scale is with respect to the Fermi energy. Gaussian fit (grey solid line) was used to determine the valence band. c, Energy diagram comparing the alignment between the control and ammonium ligand treated films. The dashed lines indicate work functions. 345FAn induces the n-type perovskite film.

FIG. 26 includes graphs 26a and 26b of absolute intensity PL spectra of perovskite thin films on glass/ITO/2PACz without (26a) or with (26b) a 30 nm-thick C₆₀ overlayer. The corresponding PLQY and QFLS values are summarized in Table 3.

FIG. 27 shows Voc-light intensity dependence of PSCs. The values of the ideality factor for control, PEA, An, and 345FAn devices are 1.13, 1.19, 1.12, and 1.07, respectively. It is noted that no direct correlation between ideality factor and device performance is found herein. This can be explained by recent findings: Although non-radiative bulk recombination leads to a higher ideality factor, surface and interface recombination can lead to a lower one. In addition, the ideality factor in perovskites solar cells can also be critically affected by the ionic nature of the absorber layer.

FIG. 28 includes graphs 28a to 28d of J-V characteristics of control (28a) and PEA (28b), An (28c), and 345FAn (28d) treated PSCs. The details behind the shown J-V curves can be found in supplementary text. Losses due to non-radiative recombination appear in Voc and FF, transport losses apparent between the transport limit J-V curve and the measured J-V curve additionally lower the FF.

FIG. 29 is a breakdown of energy loss in PSCs derived from the J-V fits.

FIG. 30 shows PV performance of PEA and 345FAn treated PSCs as a function of solution exposure times, including graphs 30a and 30b of PV parameters, including Jsc, Voc, and FF, of PEA (30a) and 345FAn (30b) treated devices with different solution exposure times (8 devices for each condition). Data are presented as mean values±standard deviation.

FIG. 31 shows device performance of PSCs with different An-derivative passivation, including graphs 31a and 31b with 31a being PCE statistics for 35tbuAn, 26FAn, and 4FAn-treated PSCs (8 devices for each type), and 31b being PCE evolution of ligand-treated devices as a function of solution exposure time (8 devices for each condition). Data are presented as mean values±standard deviation. The grey dash line is the PCE evolution of PEA-treated devices.

FIG. 32 shows photovoltaic performance of control and 345FAn treated perovskite solar modules, including graphs 32a and 32b of J-V curves (32a) and PCE statistics (32b) of control and 345FAn treated perovskite solar module with an active area of 22 cm². Inset: Photograph of a representative perovskite solar module.

FIG. 33 is graphs of J-V curves and figures of merit for devices used in stability testing. The device architecture is ITO/2PACz/Perovskite/C₆₀/ALD-SnOx/Ag and the perovskite composition is CS_{0.05}MA_{0.05}FA_{0.9}Pb(I_{0.95}Br_{0.05})₃.

FIG. 34 shows MPP tracking of encapsulated BA and OA devices at 85° C. with a relative humidity of ˜50% under 0.8-sun illumination. PEA and 345FAn results, as presented in FIG. 5E, are included for reference.

FIG. 35 shows linear extrapolation of stability testing. Based on the initial 500 h stability data, we estimate the 780 lifetime to be ˜810 h for the 345FAn-treated PSC using linear extrapolation.

FIG. 36 includes schematic 36a of a solar cell architecture including the perovskite system as defined herein, and J-V curve (36b) for the solar cell (referred to as FTO device) used in stability testing. The perovskite composition is CS_{0.05}MA_{0.05}FA_{0.9}Pb(I_{0.95}Br_{0.05})₃. The J-V curve was measured under 1-sun-equivalent white LED illumination at room temperature.

### DETAILED DESCRIPTION

The present techniques relate to interfacial capping of perovskite films to form a solar cell perovskite system that can be part of a perovskite solar cell (PSC) for enhancing stability thereof. Anilinium-based ligands can be used as surface-capping ligands that are distributed onto the surface of the perovskite film for capping thereof. In some implementations, the anilinium-based ligand can be a surface-passivating ligand that is tailored to provide passivation of the surface of the perovskite film.

A perovskite film as encompassed herein includes ABX₃ perovskites having a three-dimensional (3D) heterostructure being characterized by a tetragonal perovskite surface. A includes at least one of methylammonium (MA), formamidinium (FA), cesium (Cs) or guanidinium (GUA). B can be Pb or Sn. X includes at least one of I, Br or Cl. For example, the perovskite film consists of MAPbI₃. In another example, the perovskite film consists of CS_{0.05}MA_{0.05}FA_{0.9}Pb(I_{0.95}Br_{0.05})₃. In another example, the perovskite film consists of CS_{0.05}MA_{0.15}FA_{0.8}PbI₃.

Non-invasive/reactive surface-capping ligands are proposed herein to cap the tetragonal perovskite surface and form an interfacial layer, thereby capping the perovskite film. The terms “non-invasive” and “non-reactive” refer herein to at least minimization and preferably absence of ligand intercalation and penetration in the 3D heterostructure of the perovskite film that cause conversion of the 3D-phase of the perovskite film in 2D-phase.

Contemplated surface-capping ligands are ammonium ligands, and more particularly anilinium (An)-based ligands, that are localized and distributed at the tetragonal perovskite surface of the perovskite film, while being non-reactive with the perovskites. Anilinium-based ligands include anilinium ligand and derivatives thereof, such as alkyl anilinium ligands and fluorinated anilinium ligands. It is noted that the surface of the perovskite film, once capped with the interfacial capping layer as defined herein, can be referred to as a ligand-treated surface, including a An-treated surface.

It is noted that the extent of capping can be such that capping can be referred to as passivating. The surface-capping ligand can thus be a surface-passivating ligand. Surface-passivating ligand as encompassed herein include fluorinated anilinium ligands.

When referring to capping by the distributing of the anilinium-based ligand onto the perovskite film surface, one should understand that a single type of anilinium-based ligand or a mixture of different types of anilinium-based ligands can be used.

In some implementations, the anilinium-based ligand can be anilinium, alkyl anilinium, fluorinated anilinium or any mixtures thereof.

In some implementations, the fluorinated anilinium ligand can be is 2-fluoroanilinium (2FAn), 3-fluoroanilinium (3FAn), 4-fluoroanilinium (4FAn), 2,6-difluoroanilinium (26FAn), 3,4,5-trifluoroanilinium (345FAn), 2,3,4,5,6-pentafluoroanilinium (23456FAn), or any mixtures thereof.

In some implementations, the alkyl anilinium ligand can be tert-butyl-substituted 3,5-di-tert-butylanilinium, 3-tert-butylanilinium, 4-tert-butylanilinium, or any mixtures thereof.

Although availability of characterization techniques allowing to compare ligand reactivity is limited in view of the ultrathin nature (e.g., <10 nm) of the capping layer, the present description successfully includes experimental results showing how the molecular structure of a variety of tested ligands can affect ligand reactivity with the 3D heterostructure of the perovskite film.

### Spectroscopy Studies of Ammonium Ligands in Perovskites

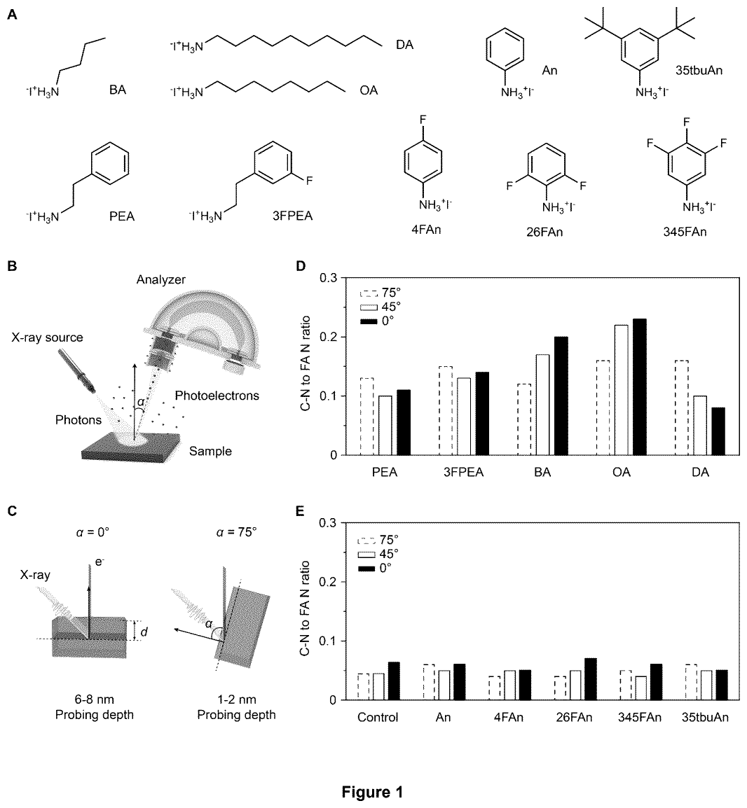

Angle-resolved x-ray photoelectron spectroscopy (AR-XPS) and time-of-flight secondary ion mass spectrometry (TOF-SIMS) were used to investigate penetration of a library of ammonium ligands into the bulk of perovskites (FIG. 1A), which include varying tail groups and alkyl chain lengths. A small-sized ammonium ligand, anilinium (An), had the lowest reactivity with 3D perovskites. Derivatives of An with different degrees of fluorination were further tested to couple low ligand reactivity with effectual interfacial passivation. These molecules improved operating stability for the encapsulated PSC at 85° C. and 50% RH.

As further described in more details in the Materials and methods section, ammonium ligands were deposited on example CS_{0.05}MA_{0.05}FA_{0.9}Pb(I_{0.95}Br_{0.05})₃ perovskite films, and films were annealed at 100° C. AR-XPS as used to probe the spatial distribution of ammonium ligands in the out-of-plane direction (FIG. 1B). AR-XPS is a nondestructive depth-profiling technique used to determine the composition of ultrathin layers (<10 nm) at the top surfaces of films. Probe depth was varied by changing the angle between the normal of the perovskite sample and the analyzer. Three different electron takeoff angles (0°, 45°, and) 75° were selected, with probe depths varying from ˜6 to 8 nm at 0° to ˜1 to 2 nm at 75° (FIG. 1C).

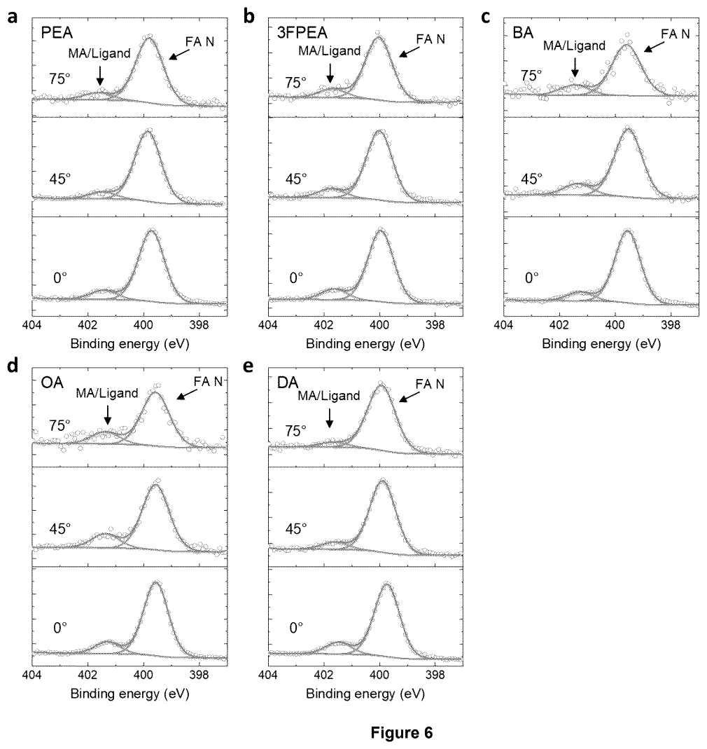

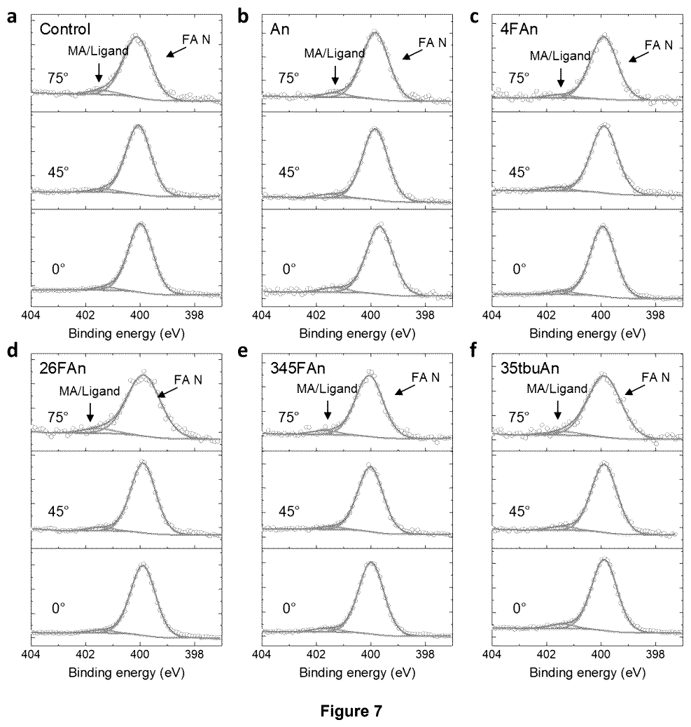

To obtain the proportion of ammonium ligands at a given probe depth, N signals (C—N) originated from methylammonium (MA) and ammonium ligands at a binding energy of ˜401.5 eV, was compared with the N signals (FA N) originating from formamidinium (FA) at a binding energy of ˜399.8 eV in the peak area in the N 1 s XPS spectrum (FIGS. 6 and 7), resulting in a C—N/FA N ratio. The C—N/FA N ratio plots (FIG. 1D) revealed that aryl ammoniums phenethyl-ammonium (PEA) and 3FPEA had relatively uniform depth distributions. By contrast, alkyl ammoniums butylammonium (BA) and octylammonium (OA) tended to accumulate on the top surfaces, as evidenced by the C—N/FA N ratio increasing with larger electron takeoff angles. However, each of the ligands yielded C—N/FA N ratios greater than those of untreated perovskites (control) for all electron takeoff angles (FIG. 1E), indicating their distinct contributions to C—N signals and their intercalation into the bulk of perovskites.

Long-chain alkyl ammonium decylammonium (DA) ligands were also examined, along with small-sized An ligand. For DA, the C—N/FA N ratio decreased with a larger electron takeoff angle (FIG. 1D). The reversed trend, as compared with other alkyl ammoniums, suggested that DA molecules diffused into the bulk of perovskites. By contrast, An exhibited low reactivity and had limited penetration into perovskites. The C—N/FA N ratios for An were a factor of ˜2 less than those for PEA at different electron takeoff angles and are similar to control perovskites (FIG. 1E).

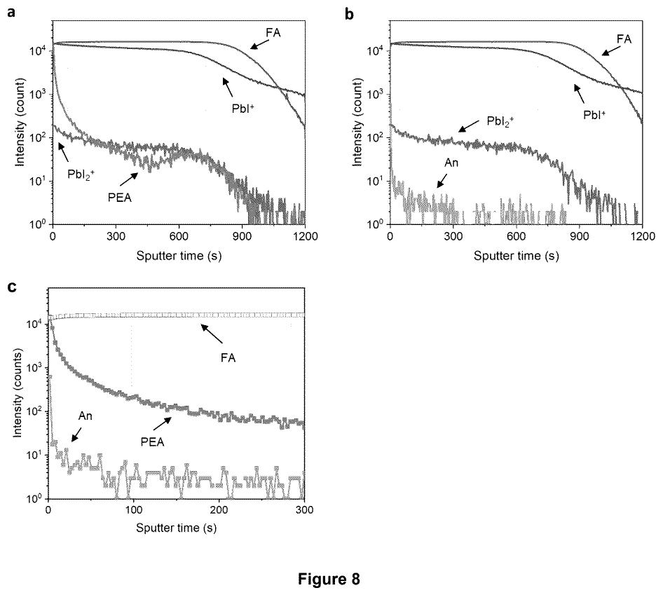

At these low C—N/FA N ratios, quantifying the extent of ligand penetration was difficult, given the prominent C—N contribution from MA cations (FIG. 7 and Table 1). We thereby performed TOF-SIMS and found that, whereas PEA cations were distributed throughout the thickness of the perovskite film, An cations were detected only at the top surface of the film (FIG. 8). The combination of AR-XPS and TOF-SIMS supported An remaining surface localized.

TABLE 1
XPS peak position and area for control and ammonium-ligand-treated
perovskite films at α = 0°, 45°, and 75° electron take-off angles

| | | C—N | | FA N | | |
|---|---|---|---|---|---|---|
| | | peak | C—N | peak | FA N | C—N to |
| | Take-off | position | peak | position | peak | FA N |
| Films | angle (°) | (eV) | area | (eV) | area | ratio |
| Control | 0 | 401.3 | 0.80 | 400.0 | 18.0 | 0.04 |
| | 45 | 401.3 | 0.74 | 400.0 | 16.5 | 0.04 |
| | 75 | 401.4 | 0.91 | 400.1 | 14.2 | 0.06 |
| PEA | 0 | 401.4 | 1.82 | 399.7 | 14.0 | 0.13 |
| | 45 | 401.5 | 1.31 | 399.8 | 13.1 | 0.10 |
| | 75 | 401.6 | 1.25 | 399.8 | 11.4 | 0.11 |
| 3FPEA | 0 | 401.6 | 2.14 | 399.9 | 14.2 | 0.15 |
| | 45 | 401.7 | 1.72 | 400.0 | 13.3 | 0.13 |
| | 75 | 401.7 | 1.54 | 400.0 | 10.9 | 0.14 |
| BA | 0 | 401.3 | 1.56 | 399.6 | 12.7 | 0.12 |
| | 45 | 401.4 | 1.78 | 399.5 | 10.5 | 0.17 |
| | 75 | 401.5 | 1.80 | 399.6 | 9.06 | 0.20 |
| OA | 0 | 401.3 | 2.31 | 399.6 | 14.2 | 0.16 |
| | 45 | 401.4 | 2.67 | 399.6 | 12.2 | 0.22 |
| | 75 | 401.4 | 2.38 | 399.6 | 10.5 | 0.23 |
| DA | 0 | 401.5 | 2.31 | 399.7 | 14.1 | 0.16 |
| | 45 | 401.6 | 1.58 | 399.9 | 15.2 | 0.10 |
| | 75 | 401.6 | 1.02 | 399.9 | 13.6 | 0.08 |
| An | 0 | 401.4 | 0.86 | 399.7 | 12.5 | 0.06 |
| | 45 | 401.5 | 0.78 | 399.8 | 15.2 | 0.05 |
| | 75 | 401.3 | 0.81 | 399.8 | 13.2 | 0.06 |
| 4FAn | 0 | 401.5 | 0.57 | 399.9 | 12.7 | 0.04 |
| | 45 | 401.6 | 0.54 | 399.9 | 10.9 | 0.05 |
| | 75 | 401.5 | 0.40 | 399.9 | 7.83 | 0.05 |
| 26FAn | 0 | 401.4 | 0.66 | 399.9 | 15.6 | 0.04 |
| | 45 | 401.4 | 0.64 | 399.9 | 12.8 | 0.05 |
| | 75 | 401.5 | 0.76 | 399.9 | 10.1 | 0.07 |
| 345FAn | 0 | 401.6 | 0.83 | 400.0 | 16.1 | 0.05 |
| | 45 | 401.5 | 0.57 | 400.0 | 14.1 | 0.04 |
| | 75 | 401.7 | 0.77 | 400.0 | 11.7 | 0.06 |
| 35tbuAn | 0 | 401.4 | 0.90 | 399.9 | 14.7 | 0.06 |
| | 45 | 401.4 | 0.68 | 399.9 | 12.4 | 0.05 |
| | 75 | 401.4 | 0.16 | 399.9 | 3.2 | 0.05 |

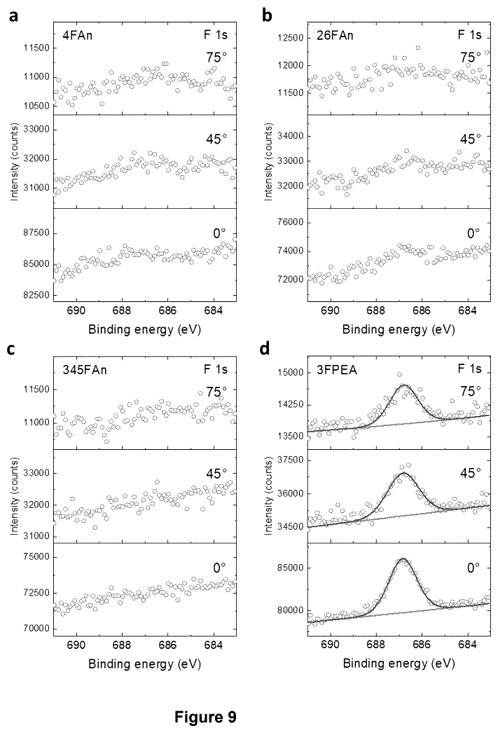

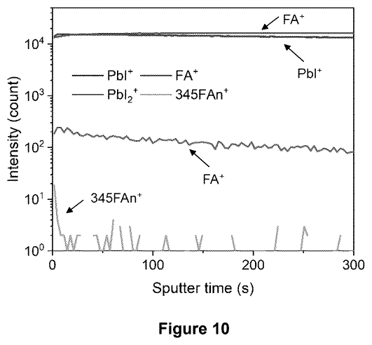

Other An-based ligand were tested to explore further promotion of interfacial passivation. Other An-based ligand included fluorinated An, such as 4-fluoroanilinium (4FAn), 2,6-difluoroanilinium (26FAn), and 3,4,5-trifluoroanilinium (345FAn), as well as alkyl anilinium, such as tert-butyl-substituted 3,5-di-tert-butylanilinium (35tbuAn). The C—N/FA N ratios (FIG. 1E) revealed that, compared with An, the newly synthesized ligands retained similarly low reactivity with perovskites. For fluorinated An, this low reactivity was also seen in the C—F signal in the F 1 s XPS spectrum (FIG. 9). We identified a distinct C—F peak for 3FPEA, whereas the C—F signals from 4FAn, 26FAn, and 345FAn were all below the detection limit at the different electron takeoff angles. TOF-SIMS further confirmed that 345FAn cations were localized to the surface of the perovskite film (FIG. 10).

The An-based ligand as proposed herein can be also characterized by a C—N/FA N ratio in the perovskite solar cell system of at most 0.1, optionally of at most 0.05, measured by angle-resolved x-ray photoelectron spectroscopy (AR-XPS).

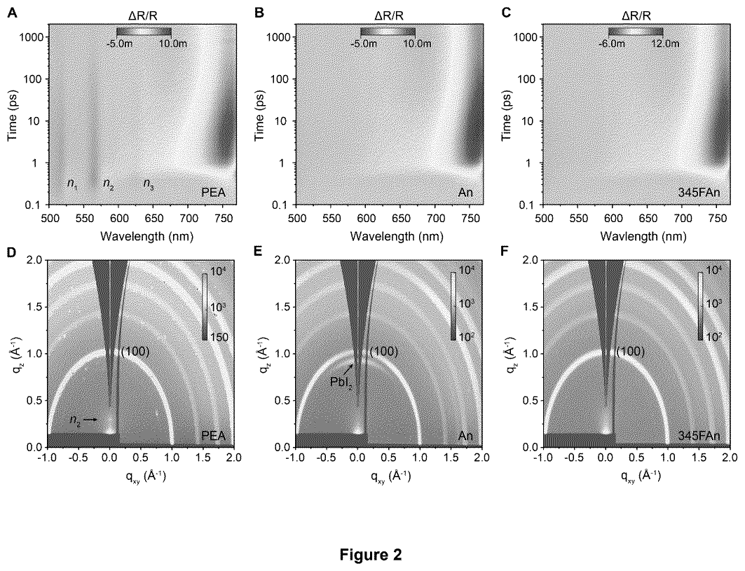

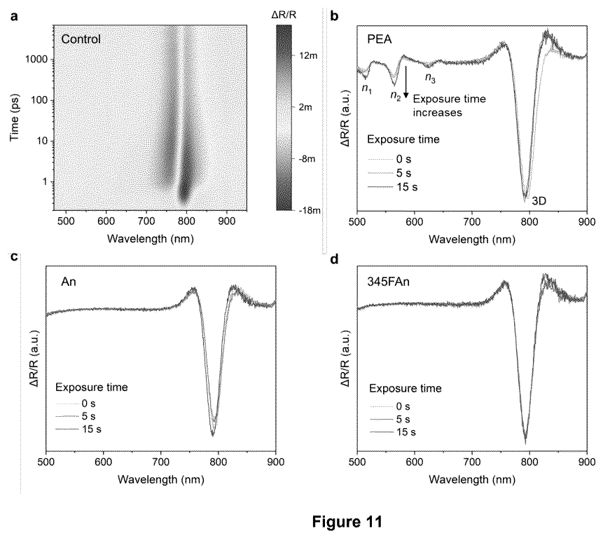

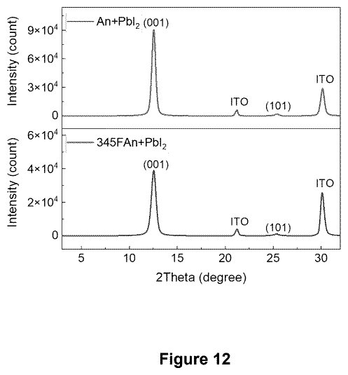

The phase transformation of perovskites driven by their interaction with ammonium ligands was further characterized. Ultrafast transient reflection (TR) spectroscopy was used initially to detect 2D perovskite formation. For the PEA-treated perovskite films, negative reflectance features associated with n=1, 2, and 3 layered 2D perovskites were observed in the TR spectra (FIG. 2A). The relative proportion of 2D phases increased as the solution exposure time was prolonged (FIG. 11) and was indicative of progressive phase transformation. For the An- and 345FAn-treated perovskite films, no 2D phases were observed (FIG. 2, B and C), which was attributed to their inability to convert 3D perovskites into 2D phases (FIG. 12). These results reinforce the model proposing that inhibiting 2D phase conversion would also reduce ligand penetration.

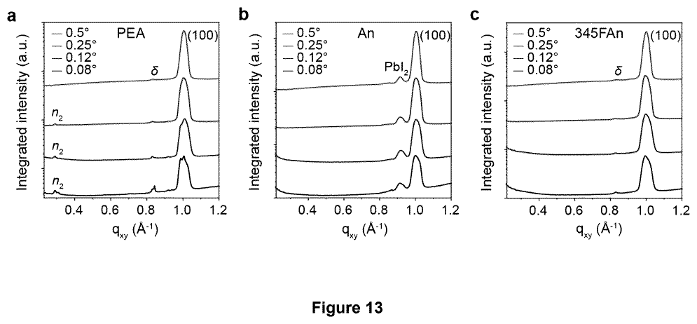

2D-phase transformation was further investigated with grazing incidence wide-angle x-ray scattering (GIWAXS) measurements. Consistent with the TR studies, n=2, 2D perovskites were observed at around q=0.29 Å⁻¹ along q_{z} for the PEA-treated perovskite film (FIG. 2D) that blocks vertical carrier transport. Incidence angle-dependent diffraction patterns of PEA-treated perovskites revealed that the 2D phase formation was more pronounced near the surface (FIG. 13). No 2D phase was detected in the An- and 345FAn-treated perovskites (FIGS. 2E and 2F).

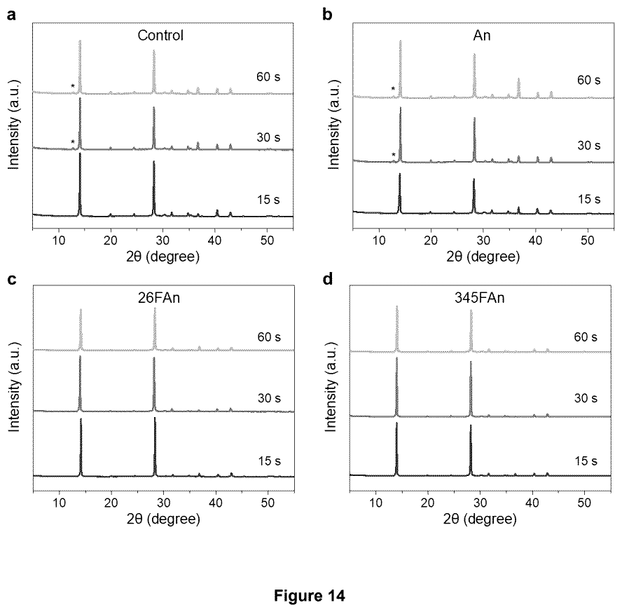

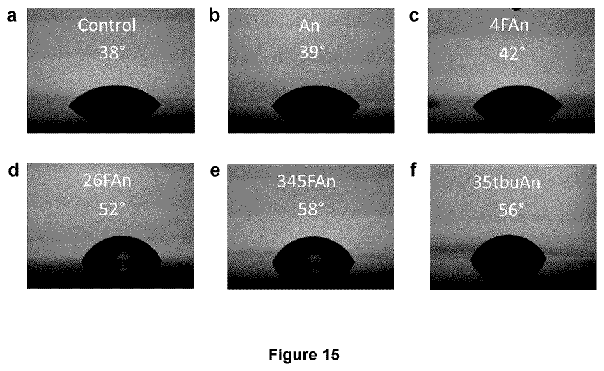

In addition, the formation of PbI₂ was observed at q=0.9 Å⁻¹ for An-treated perovskite films, which was attributed to polar solvent-induced decomposition during solution exposure, as seen in x-ray diffraction (XRD) characterization (FIG. 14). GIWAXS characterization showed that 345FAn protected the underlying perovskites from this solvent-induced degradation (FIG. 2F). It was found that the surface degradation was reduced with increased hydrophobicity of the fluorinated ligand (FIG. 15).

### Theoretical Calculations

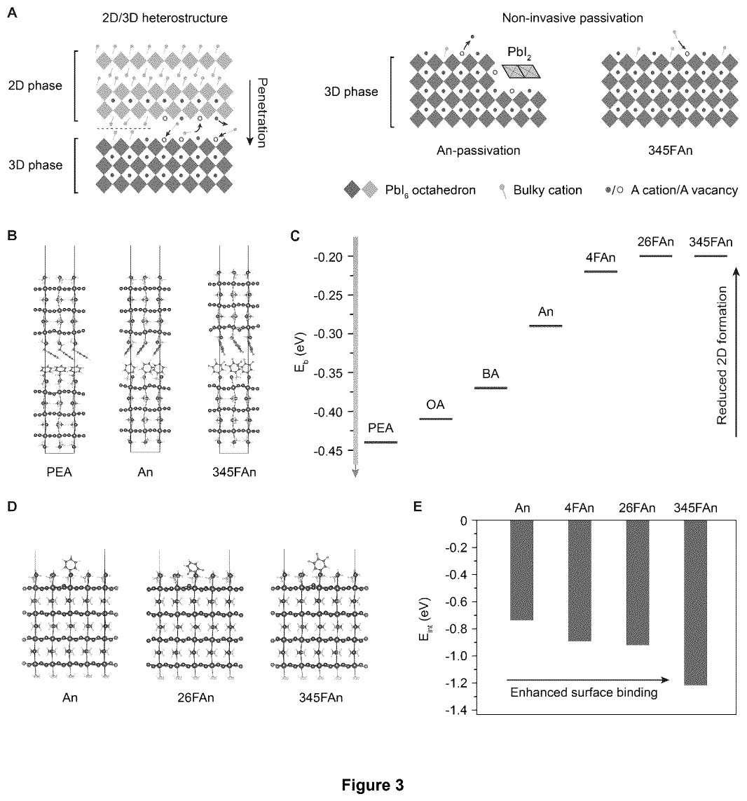

The interactions of ammonium ligands and perovskites are depicted in FIG. 3A. Density functional theory (DFT) calculations were performed to explore how molecular structure can affect these interactions. The binding energies (E_{b}) of two adjacent perovskite fragments were first calculated at their interface with the insertion of ammonium ligands (FIG. 3B). A more negative E_{b} implies that it is thermodynamically more favorable to form the 2D/3D heterostructures. Consistent with the AR-XPS studies, penetrating PEA had a more negative E_{b} value than alkyl ammoniums OA and BA, whereas An and its derivatives showed the least tendency to form 2D/3D structures (FIG. 3C).

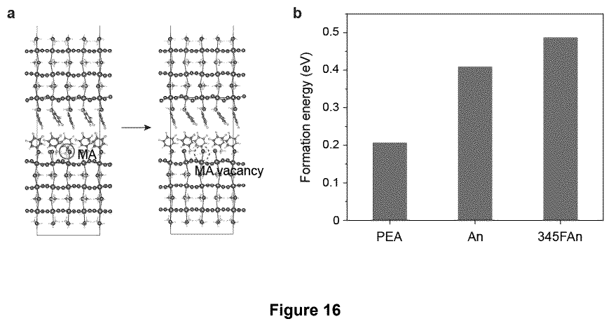

The formation of 2D perovskites can be related to steric hindrance around the NH₃⁺ group of the ligands. The steric effect index (STEI, defined as the steric environment around the NH₃⁺ group of the ammonium ligand) was determined and it was found that An had a much larger STEI (2.34) than that of PEA (1.21). The An-based ligand as proposed herein can be characterized by the steric effect index (STEI), such STEI being of at least 2, at least 2.1, at least 2.2, at least 2.3 or at least 2.4 as calculated by density-functional theory (DFT) calculations. Furthermore, phase transformation entails the replacement of A-site cations at 2D/3D interfaces. DFT calculations indicated that this process demanded more energy for An-intercalated interfaces than for PEA-intercalated ones (FIG. 16). This evidence further supported that An-based ligand is found to be less likely to penetrate the bulk of perovskites through ligand intercalation.

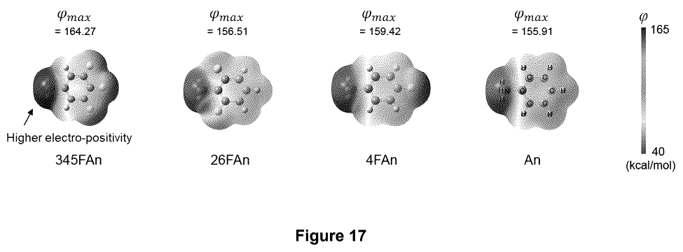

Interactions between ammonium ligands and perovskite surfaces were further examined by calculating the interaction energy (Eᵢₙₜ) for the scenario in which an ammonium ligand occupied an MA-vacancy site on the perovskite surface (FIG. 3D). Electrostatic potential calculations showed that fluorine substitution resulted in a higher positive charge density near the ammonium group (FIG. 17) that could enhance its binding with the negatively charged MA vacancy. Indeed, the Ent values were −0.74, −0.89, −0.92, and −1.22 eV/for An, 4FAn, 26FAn, 345FAn, respectively (FIG. 3E), indicating that 345FAn exhibited the strongest interaction with the perovskite surface. Future computational studies could beneficially predict the binding energy of the N 1 s XPS peak.

### Perovskite Degradation and Solar Cell Studies

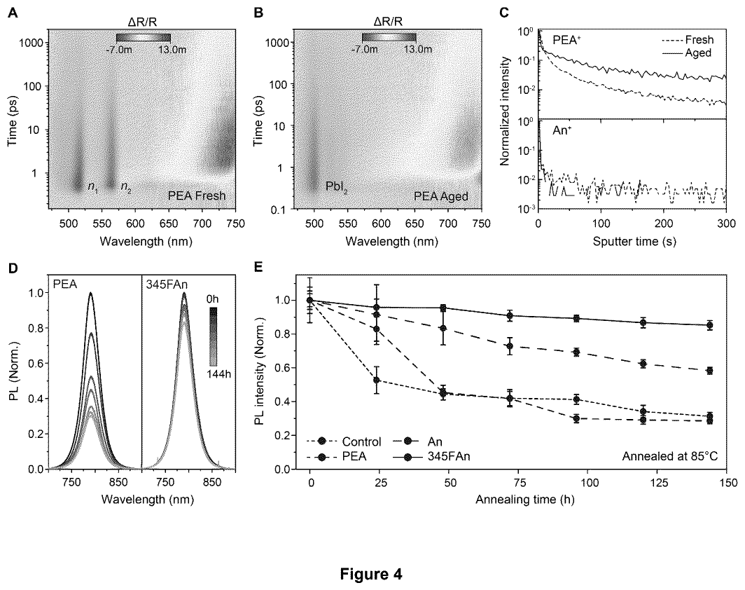

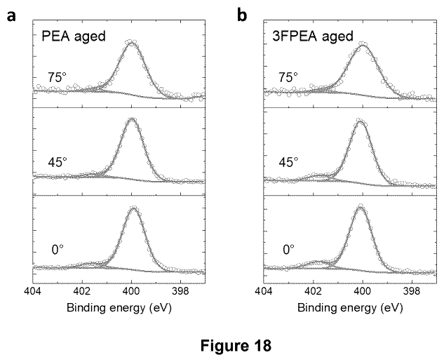

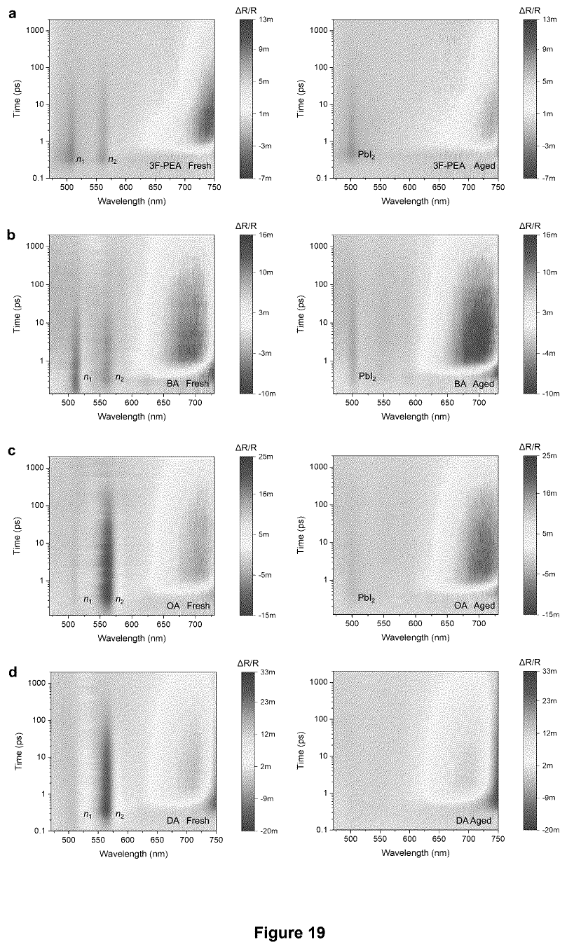

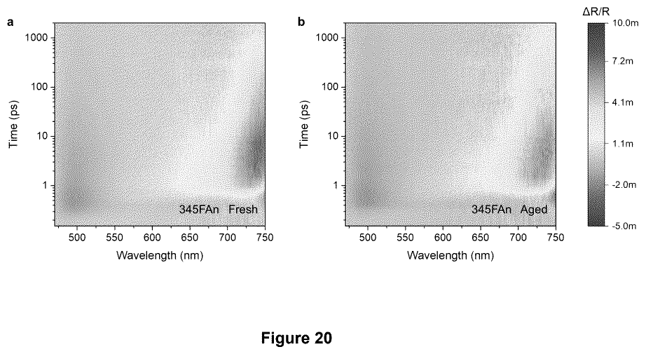

TR and TOF-SIMS were used to study perovskite degradation. The TR results indicated that PEA-based 2D perovskites were thermally unstable on the film surface and decomposed into PbI₂ after thermal aging at 85° C. for 2 hours (FIGS. 4A and 4B). This process was associated with the diffusion of PEA cations into bulk perovskites, as was seen with TOF-SIMS (FIG. 4C) and AR-XPS (FIG. 18). The dynamic nature of 2D/3D heterostructures was also confirmed for BA, OA, DA, and 3FPEA (FIG. 19). By contrast, neither ligand penetration nor phase degradation was observed for An- and 345FAn-treated films (FIG. 4C and FIG. 20). These results suggested that suppressing ligand intercalation into 3D perovskites improved interface stability under thermal stress.

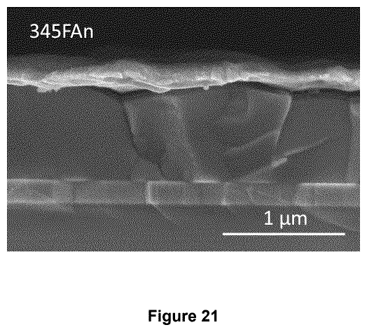

Photoluminescence (PL) stability of perovskite films after annealing at 85° C. was also determined as showed in FIG. 4D. The emission intensity of the untreated control and PEA-treated films degraded to 30% of its initial value within 144 hours (FIG. 4E). By contrast, An- and 345FAn-treated films show improved thermal stability, and 345FAn-treated perovskites retained 85% of their initial brightness after annealing. An inverted-structure PSCs was fabricated to investigate how ammonium ligands influenced the efficiency and stability of PSCs. Both CS_{0.05}MA_{0.05}FA_{0.9}Pb(I_{0.95}Br_{0.05})₃ and CS_{0.05}MA_{0.15}FA_{0.8}PbI₃ perovskites were used as an absorber, a self-assembled monolayer 2PACz was used as a hole transport layer, a thermally evaporated C₆₀/bathocuproine (BCP) bilayer was used as an electron transport layer, and indium tin oxide (ITO) was used as a transparent electrode (see further details in materials and methods). Three representative ammonium ligands, including the 2D-forming PEA cation and the non-invasive An and 345FAn cations, were used for interfacial engineering. The cross-sectional scanning electron micro-scope (SEM) image of a complete PSC device is shown in FIG. 21.

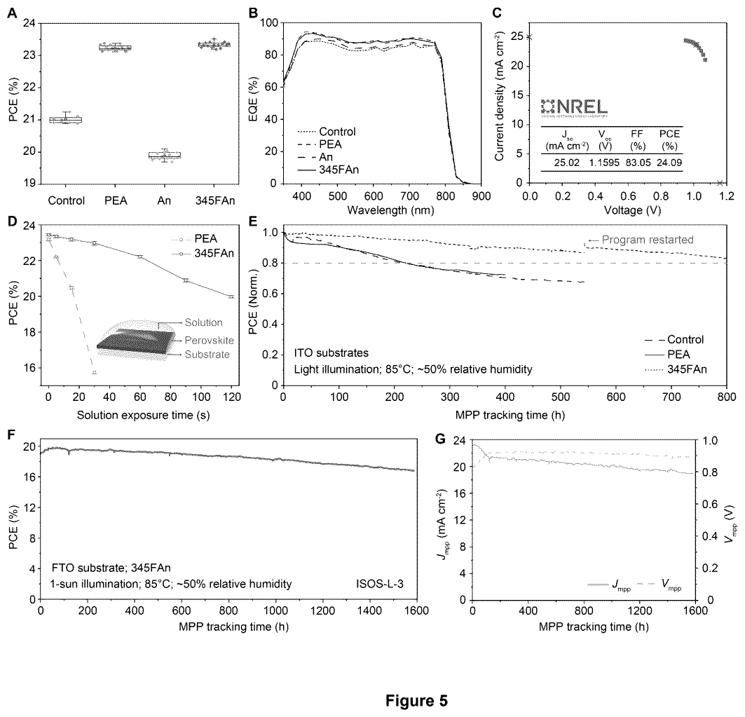

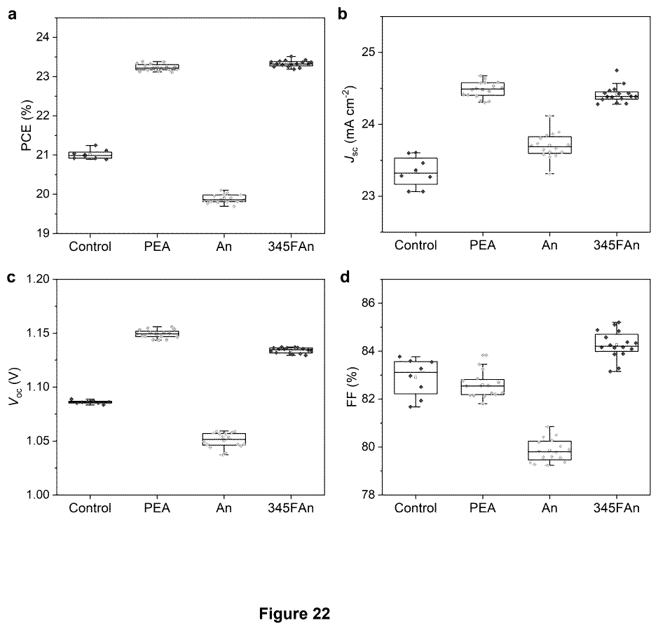

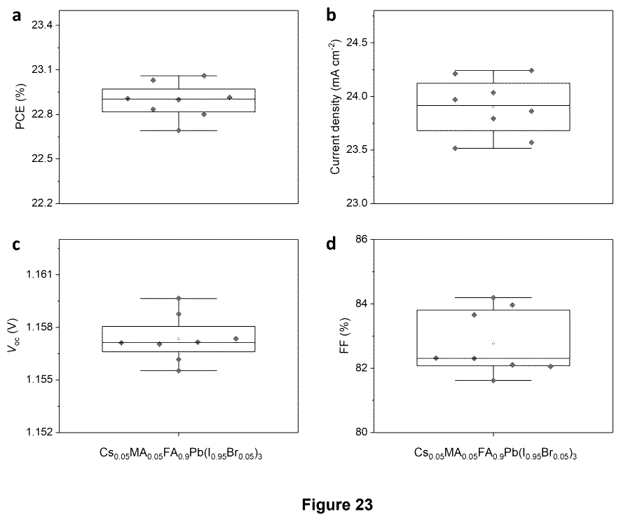

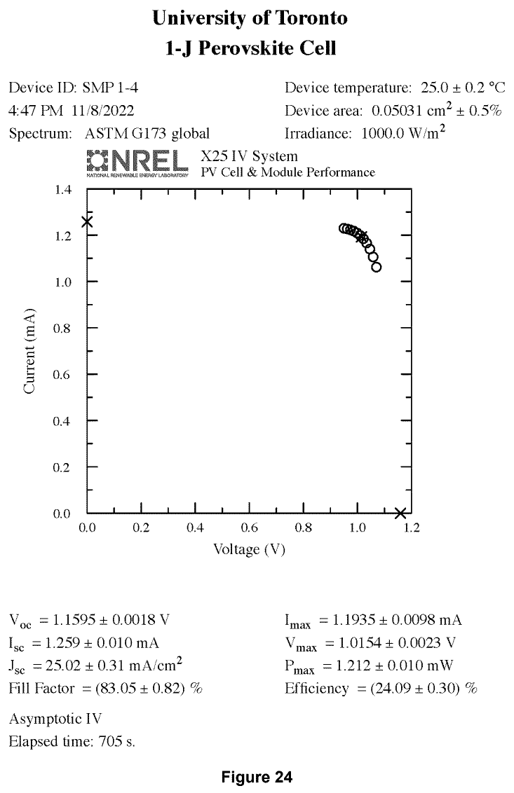

Device performance (FIG. 5A) showed that compared with control devices, PEA-treated CS_{0.05}MA_{0.15}FA_{0.8}PbI₃ PSCs (16 devices) provided improved PV performance with an average PCE of 23.2% (FIG. 5A and FIG. 22). The average PCE of An devices decreased to 19.9%, a finding that can be linked to perovskite decomposition. Because of the improved surface passivation, 345FAn treatment increased average PCEs of CS_{0.05}MA_{0.15}FA_{0.8}PbI₃ and CS_{0.05}MA_{0.05}FA_{0.9}Pb(I_{0.95}Br_{0.05})₃ PSCs to 23.3 and 22.9%, respectively (FIG. 5A and FIG. 23). The external quantum efficiency (EQE) spectra of the champion cells (FIG. 5B) for PEA and 345FAn devices exhibited improved charge collection compared with controls, and their integrated short-circuit current density (Jsc) values matched well with those from the current-voltage (I-V) sweep. A 345FAn-treated Cs_{0.05}MA_{0.15}FA_{0.8}PbI₃ device was sent to National Renewable Energy Laboratory (NREL, USA) for independent characterization. The device delivered a certified PCE of 24.09% by using a quasi-steady-state (QSS) I-V sweep (FIG. 5C and FIG. 24). The QSS-certified efficiency reported for inverted PSCs is compared with that of other devices in Table 2.

TABLE 2
Summary of quasi-steady-state (QSS) certified
PV parameters of >21% PCE inverted PSCs

| Jsc | | | | |
|---|---|---|---|---|
| Voc (V) | (mA cm−2) | FF (%) | PCE | Ref. |
| 1.1595 | 25.02 | 83.05 | 24.09% (NREL) | This work |
| 1.1607 | 25.44 | 81.48 | 24.05% (NREL) | Q. Jiang et al. |
| | | | | (2022) |
| 1.1505 | 24.90 | 83.46 | 23.91% (NREL) | H. Chen, Nat. |
| | | | | Photonics (2022) |
| 1.1687 | 22.89 | 84.55 | 22.62% (NREL) | S. Chen, Sci. Adv |
| | | | | (2021) |
| 1.1429 | 23.84 | 82.0 | 22.34% | X. Zheng, Nat. |
| | | | (Newport) | Energy (2020) (63) |

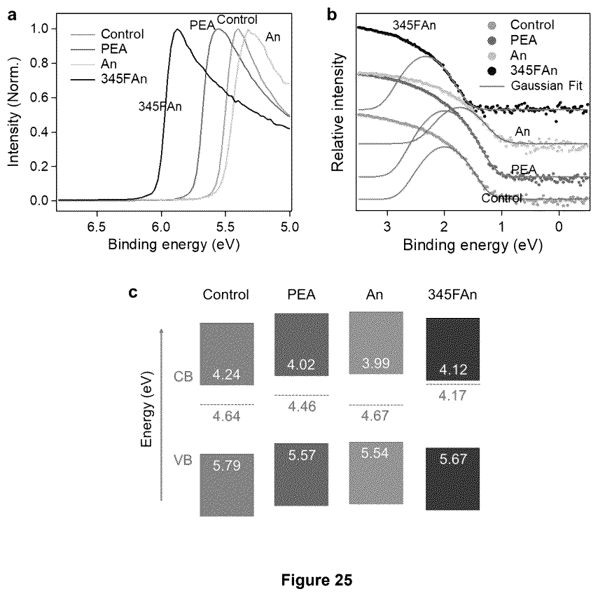

Seeking a better understanding of the improved performance, ultraviolet photoelectron spectroscopy (UPS) was used to characterize the electronic structure of the perovskite films. The secondary electron cutoff spectra (FIG. 25 showed that 345FAn decreased the work function of perovskites from 4.64 to 4.17 eV and shifted the valence-band maximum from 1.15 eV below the Fermi level in the control perovskites to 1.50 eV below the Fermi level. These results show that 345FAn induced more n-type character in the perovskite film (FIG. 25), which in inverted PSCs leads to favorable band bending for electron extraction and a decrease in nonradiative carrier recombination.

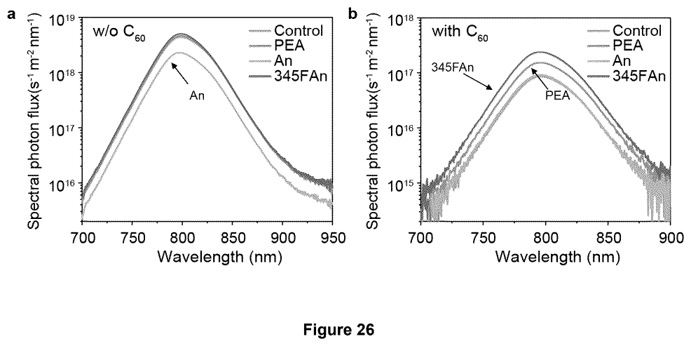

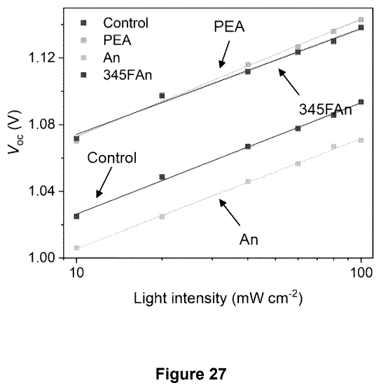

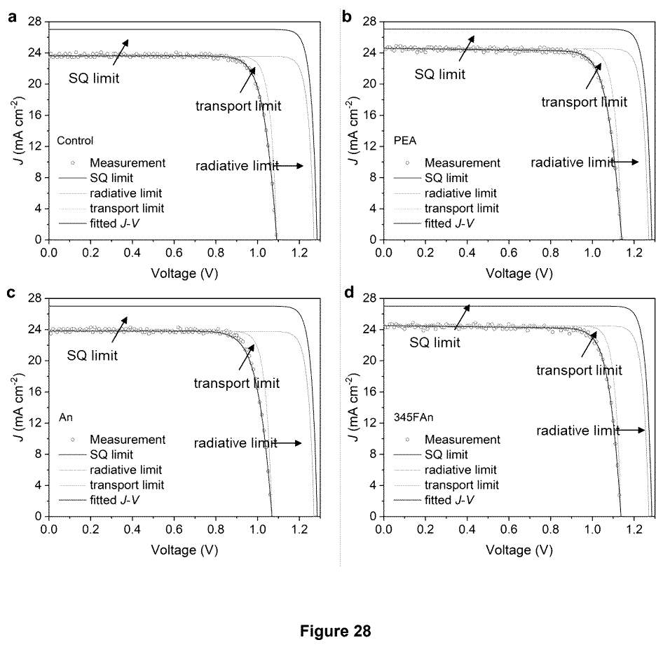

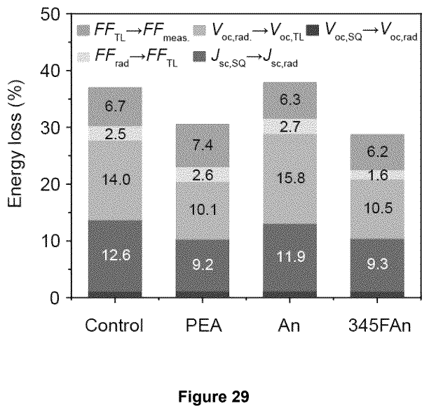

Optoelectronic characterization was further performed to investigate carrier recombination. From photoluminescence quantum yield (PLQY) measurements, nonradiative recombination at the perovskite/C₆₀ interface was found as the limiting factor for the performance of control devices (FIG. 26). This recombination loss corresponded to a reduction of the quasi-Fermi level splitting (QFLS) by ˜100 meV (Table 3). PEA and 345FAn passivation was found to reduce the interfacial non-radiative recombination, as reflected by the improved QFLS relative to the control stack, by ˜15 and ˜30 meV, respectively. The energy loss of PSCs was also evaluated on the basis of the device diode characteristics (FIGS. 27 and 28). Consistent with the PL studies, nonradiative losses were reduced for PEA and 345FAn devices (12.7 and 12.1% for PEA and 345FAn, respectively) compared with those of the control device (16.5%) (FIG. 29).

TABLE 3
Summary of PL peak position, PLQY, Voc, rad, and QFLS for
the perovskite thin films with or without the C60 overlayer

| | | PL peak | | | |
|---|---|---|---|---|---|
| | | position | | | |
| Films | Overlayer | (nm) | PLQY (%) | Voc, rad (V) | QFLS (eV) |
| Control | None | 799 | 13.4 | 1.265 | 1.213 |
| | C60 | 796 | 0.26 | 1.269 | 1.117 |
| PEA | None | 798 | 13.9 | 1.265 | 1.214 |
| | C60 | 797 | 0.47 | 1.270 | 1.132 |
| An | None | 797 | 7.0 | 1.266 | 1.198 |
| | C60 | 796 | 0.28 | 1.270 | 1.119 |
| 345FAn | None | 799 | 15.0 | 1.266 | 1.217 |
| | C60 | 795 | 0.73 | 1.271 | 1.144 |

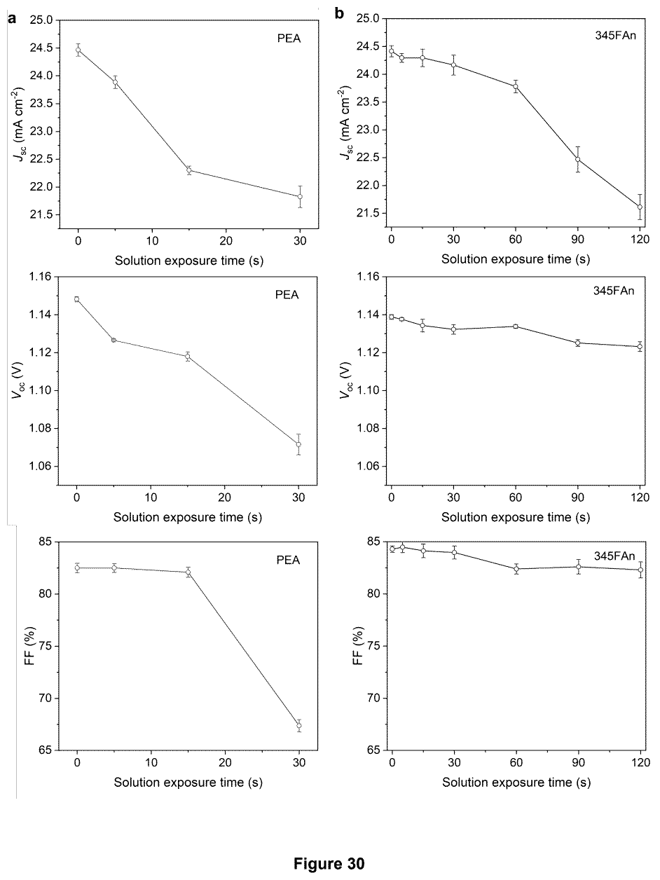

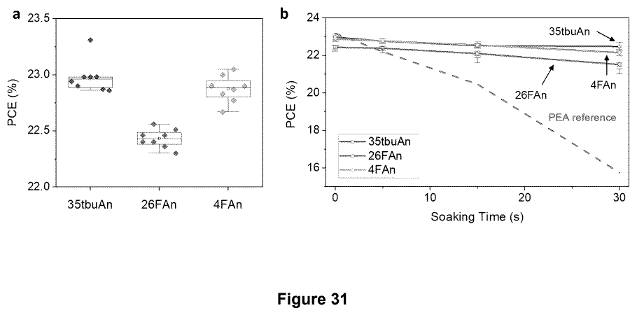

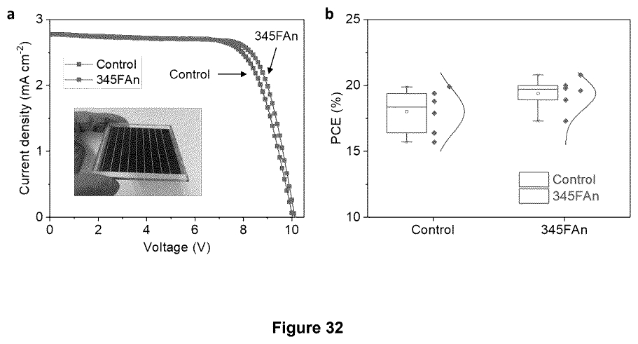

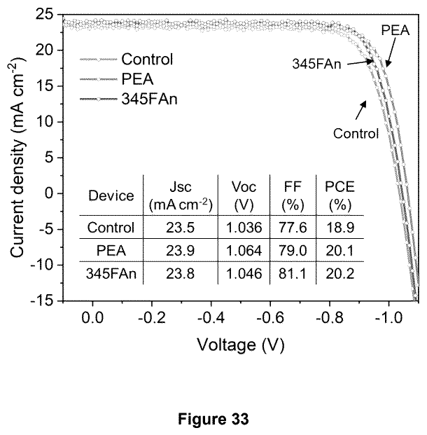

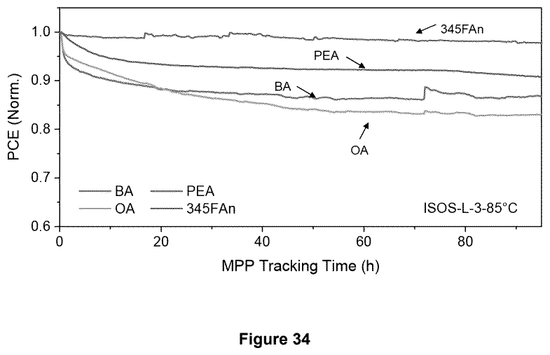

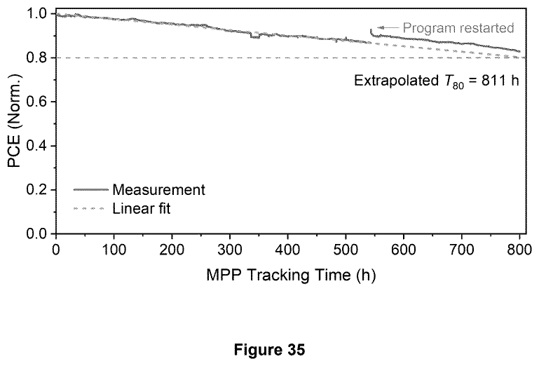

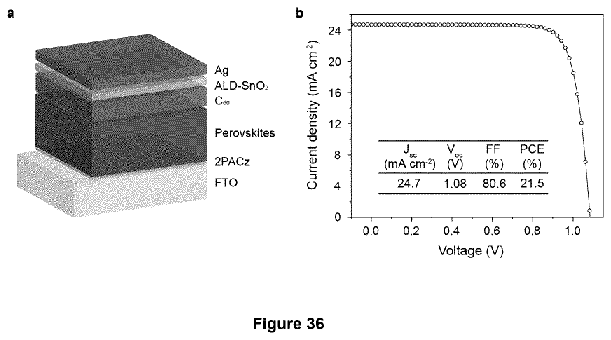

The effect of ligand reactivity on the material processing of PSCs was evaluated. The solution exposure time was varied between 0 s (dynamic spinning) and 120 s and PV parameters of PSCs were tracked accordingly (FIG. 5D and FIG. 30). The average PCE of PEA devices (eight devices for each condition) dropped to 15.8%, with an average fill factor (FF) of merely 67.4% over the course of solution exposure for 30 s, whereas 345FAn devices maintained an average PCE of 23.0% (FIG. 5D). Wide solution-processing windows were also achieved for other non-penetrating ligands, such as 35tbuAn, 4FAn, and 26FAn (FIG. 31). In pursuit of initial evidence of capacity to scale area, perovskite solar modules (PSMs) were fabricated with an active area of 22 cm² and nine interconnected subcells (see further details in materials and methods section). The champion PCE under reverse voltage scan was improved from 19.9 to 20.8% for the 345FAn-treated PSMs, with an open-circuit voltage (Voc) of 10.13 V, an FF of 74.2%, and a J_{sc} of 2.77 mA cm-2 (FIG. 32). The operating stability of PSCs using ISOS protocols as also studied. Accelerated lifetime testing was performed at the ISOS-L-3-85° C. level, constituting light-soaking tests at 50% RH and 85° C. with MPP tracking. Atomic-layer deposition was used for SnO₂ as the buffer layer and Cs_{0.05}MA_{0.05}FA_{0.9}Pb(I_{0.95}Br_{0.05})₃ perovskites as the absorber (materials and methods). The initial PCEs of the encapsulated control, PEA, and 345FAn devices were 18.9, 20.1, and 20.2%, respectively (FIG. 33). The stability results are shown in FIG. 5E. A similar T₈₀ of ˜220 hours was recorded for the control and PEA devices, in accordance with the limited thermal stability of perovskite films (FIG. 3E). 2D/3D PSCs based on alkyl ammonium BA and OA were found even less stable than the control device (FIG. 34). By contrast, the 345FAn device retained >80% of its initial value after the 800-hour test. The T₈₀ for the 345FAn device as estimated to be ˜810 hours (FIG. 35), representing a fourfold enhancement over the operating lifetime of the PEA device. To improve the T₈₀ further, fluorine-doped tin oxide (FTO) was used as an alternative transparent electrode (FIG. 36) because of its chemical stability. MPP of the encapsulated device under 1-sun illumination at 50% RH and 85° C. was monitored. The initial PCE was 19.0%, which increased progressively to a peak value of 19.9% after ˜50 hours of operation (FIG. 5F). This maximum PCE (PCEₘₐₓ) corresponds to a temperature coefficient of −0.12%/° C. relative to the room temperature device PCE (21.5%), which is consistent with known results for inverted PSCs. After 1586 hours of continuous operation, the PCE dropped to 16.8% (84% of the PCEₘₐₓ), primarily because of a reduction in current density (FIG. 5G). The T₈₅ Was determined to be ˜1560 hours (FIG. 5F). A comparison with other ISOS-L-3-stable PSCs is provided in Table 4.

TABLE 4
Summary of reported device operational stability based on ISOS-L-3 protocols.

| Light | | | Surface | PCE | | |
|---|---|---|---|---|---|---|
| source | T | Environment | passivation | @high-T | Lifetime | Ref. |
| White LED | 85° C. | ~50% RH | 345FAn | 19.9% | T 85 = 1560 h | This work |
| | | | | (85° C.) | | |
| White LED | 65° C. | ~50% RH | 3FPEA | N.A. | T 92 = 500 h | H. Chen, |
| | | | 2D/3D | | | Nat. Photonics |
| | | | | | | (2022) |
| Metal-halide | 85° C. | ~65% RH | Cs2Pbl2Cl2 | ~16.5% | T 85 = 4000 h | X. Zhao, Science |
| lamp | | | | (85° C.) | | (2022) (12) |
| Xenon lamp | 85° C. | ~50% RH | None | ~14.2% | T 95 = 1200 h | Y-H. Lin, |
| | | | | (85° C.) | (Post 15% | Science (2020) |
| | | | | | burn-in) | (11) |
| Plasma | 65° C. | ~60% RH | PbSO4 | ~19.5% | T 96.8 = 1200 h | S. Yang, Science |
| lamp | | | | (65° C.) | | (2019) (18) |

Aided by spectroscopic techniques, including AR-XPS, TOF-SIMS, and TR, it was shown that certain 2D/3D heterostructures, such as those employing typical ammonium ligands including PEA, 3FPEA, BA, and OA, can undergo thermal degradation due to the dynamic nature of the interfaces at elevated temperatures. Anilinium-based ligands, including anilinium and its fluorinated derivatives, offer a more robust interface structure correlated with limited penetration into the bulk of perovskites. Specifically, fluorinated An ligand favor interface passivation linked to strong interactions with perovskite surfaces. A resulting optimized perovskite solar cell, such as optimized 345FAn device, are found to be among the most stable PSCs seen under ISOS-L-3 protocols at 85° C., achieving PCE of 19.9% during MPP tracking at this elevated operating temperature.

### Materials and Methods

### Materials

All materials were used without further purification. Organic halide salts, including methylammonium iodide (MAI), formamidinium iodide (FAI), methylammonium bromide (MABr) methylammonium chloride (MACl), were purchased from Great Cell Solar, and cesium iodide (CsI) was purchased from Sigma-Aldrich. [2-(9H-Carbazol-9-yl)ethyl]phosphonic Acid (2PACz), lead iodide (PbI₂, 99.99%), and bathocuproine (BCP) were purchased from TCI. Anhydrous solvents including N, N-dimethylformamide (DMF, 99.8%), dimethyl sulfoxide (DMSO, 99.9%), 2-propanol (IPA, 99.5%), chloroform (CF, 99.8%), chlorobenzene (CB, 99.8%), and anisole (99.7%) were purchased from Sigma-Aldrich and toluene (99.8%) was purchased from Alfa Aesar. 3-fluoro-phenethylammonium iodide (3FPEAI) and C₆₀ were purchased from Xi'an Polymer Light Technology Corp. Non-patterned indium tin oxide (ITO) coated glass substrates (15 Ω/sq) were purchased from Tinwell Technology. Commercial patterned ITO substrates (20 Ω/sq) with 25 mm×25 mm dimensions were purchased from TFD Inc.

Bulky ammonium halide salts, including anilinium iodide (AnI, TCI, 98%), butylammonium iodide (BAI, TCI, 97%), phenethylammonium iodide (PEAI, Great Cell Solar, 99%), were purchased and used as received. 4-fluoroaniline (TCI, 98%), 2,6-difluoroaniline (TCI, 98%), 3,4,5-trifluoroaniline (TCI, 98%), octylamine (Alfa Aeser, 99%), decylamine (Sigma-Aldrich, 95%), and 3,5-di-tert-butylaniline (TCI, 98%) were purchased and converted to ammonium salts using the same procedure as reported before (20). The abbreviations of the converted ammonium salts are 4-fluoroanilinium iodide (4FAnI), 2,6-difluoroanilinium iodide (26FAnI), 3,4,5-trifluoroanilinium iodide (345FAnI), 3,5-di-tert-butylanilinium iodide (35tbuAnI), octylammonium iodide (OAI), and decylammonium iodide (DAI).

### Perovskite Film Fabrication

The precursor solution (1.5 M) was prepared from CsI, MAI, FAI, PbBr₂, and PbI₂ precursors dissolved in mixed solvents of DMF and DMSO with a volume ratio of 4:1. For the Cs_{0.05}MA_{0.15}FA_{0.8}PbI₃ perovskite, the molar ratio for FAI/MAI/CsI was 0.8:0.15:0.05, and 10 mg m⁻¹ MACl was added in the solution to improve the film morphology; For the Cs_{0.05}MA_{0.05}FA_{0.9}Pb(I_{0.95}Br_{0.05})₃ perovskite, the molar ratios for FAI/MABr/CsI and PbI₂/PbBr₂ were 0.9:0.05:0.05 and 0.95:0.05, respectively. The precursor solution was filtered through a 0.22 μm polytetrafluoroethylene (PTFE) membrane before use. 60 μL of perovskite solution was deposited on the substrate and spun cast at 1000 rpm for 10 s followed by 6000 rpm for 30 s. 150 μL anisole was dropped onto the substrate during the last 5 s of the spinning, resulting in the formation of dark brown films that were then annealed on a hot plate at 100° C. for 20 min.

### Perovskite Solar Cell (PSC) Device Fabrication

The pre-patterned ITO or FTO glasses were sequentially sonicated in aqueous detergent, deionized water, acetone, and IPA each for 10 min. After drying with nitrogen, the substrates were exposed to UV-ozone treatment for 15 min to remove organic contaminants. 100 μL of 2PACz in anhydrous ethanol (1 mmol/l) solution was spun-cast at 3000 rpm for 30 s inside the nitrogen-filled glovebox (<0.1 ppm of O₂ and H₂O) and annealed at 100° C. for 10 min. Following the 2PACz coating, CS_{0.05}MA_{0.15}FA_{0.8}PbI₃ perovskites were deposited on the substrate as detailed above. 200 μL of ammonium ligand solution (1 mg/mL) in CF with an additional 3% of IPA was then drop cast within 2-3 s on the perovskite film spinning at 4000 rpm (i.e., dynamic spinning/spin-coating) and annealed at 100° C. for 5 min. For the exposure time-dependent measurements, 200 μL of ammonium ligand solution was left on the perovskite film for a certain period before spinning at 4000 rpm. Both control and treated films were then transferred to the thermal evaporator (Angstrom engineering), and C₆₀ (30 nm) and BCP (7 nm) were deposited sequentially with a rate of 0.3 Å/s and 0.5 Å/s, respectively, at a pressure of ca. 2×10⁻⁶ mbar. Finally, Ag contact (120 nm) was deposited on top of BCP through a shadow mask with the desired aperture area.

For the stability testing, Cs_{0.05}MA_{0.05}FA_{0.9}Pb(I_{0.95}Br_{0.05})₃ perovskites were instead deposited as described above, and C₆₀ (30 nm) and ALD-SnO₂ were used as the electron transport layer. The deposition of ALD-SnO₂ was carried out in the PICOSUN R-200 Advanced ALD system. H₂O and TDMASn were used as oxygen and tin precursors. Precursor and substrate temperature were set to 75° C. and 85° C., respectively. 90 SCCM N2 was used as carrier gas. Pulse and purge times for H₂O were 1 s and 5 s, and 1.6 s and 5 s for TDMASn. The total deposition cycle is 150, corresponding to 20 nm of SnO₂.

### Perovskite Solar Cell (PSC) Module Fabrication

Perovskite solar cell modules were fabricated on pre-cleaned FTO glass substrates with a size of 6×6 cm², which were patterned by a 1030 nm laser (LPKF ProtoLaser R) with nine sub-cells connected in series. FTO substrates were patterned with a laser power of 5 W (P1). The SnO₂ was used as the electron transport layer (ETL) using the chemical bath deposition method. The solution was prepared by adding 2.5 g of urea (Sigma-Aldrich, 99%), 3.5 mL of HCl (Sigma-Aldrich, 37% wt. % in water), 50 μL of thioglycolic acid (Sigma-Aldrich, 98%), and 0.55 g of SnCl₂·2H₂O (Sigma-Aldrich, 99.99%) into 200 mL of deionized water. The FTO substrates were immerged into the solution at 90° C. for 5 hours, followed by annealing at 190° C. for 1 hour. Then 1.5 M perovskite precursors with PbI₂ (TCI America, 99.99%): FAI (GreatCell Solar, 99.99%): MAI (GreatCell Solar, 99.99%): CsI (Sigma-Aldrich, 99.99%): MACl (GreatCell Solar, 99.99%)=1:0.85:0.05:0.05:0.20) were dissolved in the mixed DMF (Sigma-Aldrich, 99.8%): DMSO (Sigma-Aldrich, 99.9%)=4:1 (volume ratio) solvent. The perovskite films were deposited by spin-coating at 1000 rpm for 10 s and 5000 rpm for 30 s. At the 20 s of the second step, 200 μL of chlorobenzene (Sigma-Aldrich, 99.8%) was dropped onto the perovskite films to facilitate crystallization. The perovskite films were annealed at 100° C. for 10 min and 150° C. for 10 min. The passivation layer was fabricated by spinning 100 μL 345FAn solution (1 mg/mL) in isopropanol (Sigma-Aldrich, 99.5%) and chlorobenzene (1:1 volume ratio) at 5000 rpm for 30 s, followed by annealing at 100° C. for 10 min. The hole transport layer was deposited by spin-coating 0.06 M spiro-OMeTAD (Sigma-Aldrich, SHT-263 Solarpur) solution in chlorobenzene at 3000 rpm s. 0.03 M bis(trifluoromethanesulfonyl)-imide lithium salt (Sigma-Aldrich, 99.0%) in acetonitrile (Sigma-Aldrich, 99.8%), 0.2 M 4-tert-Butylpyridine (Sigma-Aldrich, 98%) and 0.0035 M FK 209 Co (III) TFSI salt (GreatCell Solar) in acetonitrile were added to the spiro-OMeTAD solution as additives. Then the P2 lines were patterned aligning with P1 using a laser power of 0.5 W. Finally, the electrode was realized by thermal evaporating a 70 nm gold under high vacuum, followed by P3 etching using a laser power of 0.5 W. The geometric fill factor (GFF) of 92% was defined as the active area (22.0 cm²) divided by the aperture area (23.9 cm²).

It is noted that the An-based ligand as proposed herein can also be characterized by a solubility in isopropanol between 0.5 and 5 mg m⁻¹, as determined by standard gravimetric analysis

### Solar Cell Characterization

The current-voltage (I-V) characteristics of solar cells were measured using a Keithley 2400 sourcemeter under the illumination of solar simulator (Newport, Class AAA) at the light intensity of 100 mW·cm⁻² as checked with a calibrated reference solar cell (Newport). Unless otherwise stated, the I-V curves were all measured in a nitrogen atmosphere with a scanning rate of 100 mV·s⁻¹ (voltage steps of 10 mV and a delay time of 100 ms). The active area was determined by the aperture shade mask (0.049 cm²) placed in front of the solar cell to avoid overestimation of the photocurrent density. EQE measurements were performed using Newport system (QuantX-300) with monochromatic light and white bias light (˜0.2 Sun). The system was calibrated by a certified silicon solar cell.

### Stability Tests of Solar Cells

Devices were placed in a homemade stability tracking station. The illumination source is a white light LED with intensity calibrated to match 0.8-sun conditions. For the ISOS-L-3 ageing protocol, the device chamber was left open in a room with 50±10% humidity and solar cell was mounted on a metal plate kept at 85° C. by a heating element. A thermal couple attached to the metal plate was used to monitor and provide feedback control to the heating element to ensure temperature consistency. MPP was tracked using a home-build MATLAB-based MPP tracking system using a ‘perturb and observe’ method. The MPP was updated every 1000 minutes. Encapsulation was done by capping the device with a glass slide, using UV-adhesive (Lumtec LT-U001) as a sealant.

### AR-XPS Measurements

AR-XPS measurements were performed with a Thermo Scientific K-Alpha system with 180° double-focusing, hemispherical analyzer. The system is equipped with a 128-channel detector and monochromated small spot XPS. An Al Kα source (1486.6 eV) was used for excitation and a pass energy of 147.6 eV was used for XPS acquisition. Three electron take-off angles (α=0°, 45°, and) 75° were defined as the angle between the normal of the perovskite sample and the analyzer (FIG. 1b). Samples mounted on a metal specimen holder were rotated along x, y, z directions to match the analyzing spots. All data were analyzed with Thermo Avantage software.

### TR Measurements

A regeneratively amplified Yb:KGW laser at a 5 kHz repetition rate (Light Conversion, Pharos) was used to generate femtosecond laser pulses, and a pulse picker was used to lower the frequency to 1 KHz. A portion of the 1,030 nm fundamental was sent into an optical bench (Ultrafast, Helios), where it passed through a retroreflector and was then focused into a calcium fluoride crystal, translated at 1 mm s-1, to create the white light continuum probe. An optical parametric amplifier (Light Conversion, Orpheus) was used to generate the 450 nm pump pulse by upconversion of the fundamental wavelength. This was then sent to the optical bench and was chopped at 500 Hz. Both the pump and probe were sent to the sample, with the time delay adjusted by changing the path length of the probe (time resolution ˜350 fs). The probe pulse was then collected by a CCD after dispersion by a grating spectrograph (Ultrafast). Time zero was allowed to vary with wavelength to account for the chirp of the probe.

### GIWAXS Measurements

GIWAXS measurements were performed at CMS beamline, NSLS II. The monochromatic X-ray with the energy of 13.5 keV shone upon the samples at different grazing incident angles of 0.08°, 0.12°, 0.25°, and 0.5° with an exposure time of 10 s. A Pilatus800K detector was placed 259 mm away from the sample to capture the 2D diffraction pattern.

### PL and Time-Resolved PL (TRPL) Measurements

Photoluminescence lifetime (TCSPC) was measured using an Edinburgh Instruments lifespec II fluorescence spectrometer; a picosecond pulse diode laser (EPL-510, excitation wavelength 510 nm, pulse width <60 ps, fluence <3 nJ cm-2) was used. Absolute intensity photoluminescence spectra were measured using an integrating sphere, and Andor Kymera 193i spectrograph, and a 660 nm continuous-wave laser set at 1-Sun equivalent photon flux (1.1 μm beam full-width half-maximum, 632 μW); photoluminescence was collected at normal incidence using a 0.1 NA, 110 μm-diameter optical fiber.

### TOF-SIMS Measurement

The time-of-flight secondary ion mass spectrometry (TOF-SIMS) measurements were performed on the IONTOF M6 instrument with a Bi³⁺ (30 keV) primary ion beam for analysis and an Ar-cluster gun (5 keV) for sputtering due to its low damage depth. Data was acquired for positive ions in an analysis area of 49×49 μm² centered inside the cluster raster area of 200×200 μm². No distribution gradient was observed for FA cations, indicating that measurement artifacts were successfully minimized.

### Other Characterizations

XRD spectra were collected with a Bruker-AXS D8 advance diffractometer with Cu Kα radiation (λ=1.5418 Å) operating at 40 kV and 40 mA. Contact angles were measured with a standard goniometer (Raméhart) equipped with a camera. A 4 μl drop of deionized water was placed onto the target surface and pictures were captured after 2 s of depositing the drop. The images were analyzed using ImageJ software to extract macroscale contact angle data. UPS measurements were taken with an Excitech H Lyman-α photon source (10.2 eV) with an oxygen-filled beam path coupled with the same PHI 5600 UHV and analyzer system. A sample bias of −5 V was applied and a pass energy of 5.85 eV was used for UPS acquisition. High-resolution SEM images were obtained using the Hitachi S5200 microscope with an accelerating voltage of 1.5 kV. A low accelerating voltage and a low beam current were deployed to reduce surface damage of perovskite films under electron beam bombardment.

### DFT Calculations

First-principles calculations based on density functional theory (DFT) were carried out using a Vienna Ab initio Simulation Package (VASP). The generalized gradient approximation (GGA) of Perdew-Burke-Ernzerhof (PBE) functional was employed as the exchange-correlation functional. A DFT-D3 method was adopted for the van der Waals (vdW) correction. The plane-wave cutoff energy of 400 eV was used. The energy and force convergence criteria were set to 10-5 eV and 0.02 eV·Å-1, respectively. In 2D perovskite formation calculations, the binding energies (E_{b}) of adjacent fragments was defined as: E_{B}=Eₜₒₜ−E_{fragment1}−E_{fragment2}, Where Eₜₒₜ, E_{fragment1} and E_{fragment2} are the total energies of the entire system, and two fragments cut from the optimized system. The interaction energies (Eᵢₙₜ) of different ammonium cations (L) with tetragonal MAPbI₃ perovskite surface were calculated as Eₘₒₗ/pvsk−Eₚᵥₛₖ−E_{L}, where Eₘₒₗ/pvsk, Eₚᵥₛₖ and E_{L} are the total energies of the adsorption system, the perovskite system and LI, respectively. A vacuum of 20 Å was used to separate two surfaces along the z-direction.

### Analysis of the Energy Loss of PSCs

To elucidate the origin of energy loss in PSCs, the device diode characteristics were analyzed by first obtained an ideality factor n of representative PSCs from the plots of their Voc-incident light intensity dependence (FIG. 21). Following these preparations, the energy loss of PSCs was broken down based on the following procedures: (1) The Shockley-Queisser limit was calculated from bandgap which we determined from the PL peak wavelength of the perovskite thin film within a complete device stack (FIG. 20b). The bandgaps are found to be around 1.56 eV for different films with small variations. (2) The radiative limit is calculated by using the Jsc of the studied devices, the radiative limit of V_{oc}, and assuming an ideal diode behavior (n=1; with series and shunt resistances of Rₛₑᵣᵢₑₛ=0 and Rₛₕᵤₙₜ=∞, respectively). The performance losses related to the radiative limit with respect to the Shockley-Queisser limit account for 10.4% for the PEA device and 10.5% for the 345FAn device, mainly stemming from the non-ideal light absorption. (3) The contribution of non-radiative bulk and interface recombination (i.e., non-radiative losses) is further evaluated by calculating the transport limit using the measured V_{oc} and ideality factor, while maintaining the J_{sc} and ideal resistances. Comparing the transport limit with the radiative limit, non-radiative losses are found as 12.7% and 12.1% for PEA and 345FAn devices, respectively. (4) Finally, transport losses are analyzed using the measured J-V curve with respect to the transport limit. The PEA device has a higher transport loss (7.4%) than that of 345FAn (6.2%).

It should be noted that the embodiments, geometrical configurations, materials mentioned and/or dimensions shown in the figures are optional, and are given for exemplification purposes only. Therefore, the descriptions, examples, methods and materials presented in the claims and the specification are not to be construed as limiting but rather as illustrative only.

It is worth mentioning that throughout the above description when the article “a” is used to introduce an element it does not have the meaning of “only one” it rather means of “one or more”. It is to be understood that where the specification states that a component, feature, structure, or characteristic “may”, “might”, “can” or “could” be included, that particular component, feature, structure, or characteristic is not required to be included.

In the following description, each value is provided within an acceptable error range for the particular value as determined by one of ordinary skill in the art, which will depend in part on how the value is measured or determined, i.e. the limitations of the measurement system. It is commonly accepted that a 10% precision measure is acceptable.

In the above description, an embodiment is an example or implementation of the inventions. The various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention may also be implemented in a single embodiment.

It should be understood that any one of the above-mentioned optional aspects of each system, method and use of the system as defined herein may be combined with any other of the aspects thereof, unless two aspects clearly cannot be combined due to their mutually exclusivity. For example, the various structural elements of the system described herein-above, herein-below and/or in the appended Figures, may be combined with any of the general method or use descriptions appearing herein and/or in accordance with the appended claims.

### REFERENCES

S. M. Park, A. Abtahi, A. M. Boehm, K. R. Graham, Surface Ligands for Methylammonium Lead lodide Films: Surface Coverage, Energetics, and Photovoltaic Performance. ACS Energy Lett. 5, 799-806 (2020).
H. Chen, S. Teale, B. Chen, Y. Hou, L. Grater, T. Zhu, K. Bertens, S. M. Park, H. R. Atapattu, Y. Gao, M. Wei, A. K. Johnston, Q. Zhou, K. Xu, D. Yu, C. Han, T. Cui, E. H. Jung, C. Zhou, W. Zhou, A. H. Proppe, S. Hoogland, F. Laquai, T. Filleter, K. R. Graham, Z. Ning, E. H. Sargent, Quantum-size-tuned heterostructures enable efficient and stable inverted perovskite solar cells. Nat. Photonics 16, 352-358 (2022).
C. A. R. Perini, E. Rojas-Gatjens, M. Ravello, A.-F. Castro-Mendez, J. Hidalgo, Y. An, S. Kim, B. Lai, R. Li, C. Silva-Acuña, J.-P. Correa-Baena, Interface Reconstruction from Ruddlesden-Popper Structures Impacts Stability in Lead Halide Perovskite Solar Cells. Adv. Mater. 34, 2204726 (2022).
Q. Jiang, J. Tong, Y. Xian, R. A. Kerner, S. P. Dunfield, C. Xiao, R. A. Scheidt, D. Kuciauskas, X. Wang, M. P. Hautzinger, R. Tirawat, M. C. Beard, D. P. Fenning, J. J. Berry, B. W. Larson, Y. Yan, K. Zhu, Surface reaction for efficient and stable inverted perovskite solar cells. Nature 611, 278-283 (2022)
S. Chen, X. Xiao, H. Gu, J. Huang, Iodine reduction for reproducible and high-performance perovskite solar cells and modules. Sci. Adv. 7, 1-7 (2021).
Y. Zhao, T. Heumueller, J. Zhang, J. Luo, O. Kasian, S. Langner, C. Kupfer, B. Liu, Y. Zhong, J. Elia, A. Osvet, J. Wu, C. Liu, Z. Wan, C. Jia, N. Li, J. Hauch, C. J. Brabec, A bilayer conducting polymer structure for planar perovskite solar cells with over 1,400 hours operational stability at elevated temperatures. Nat. Energy 7, 144-152 (2022).
Y.-H. Lin, N. Sakai, P. Da, J. Wu, H. C. Sansom, A. J. Ramadan, S. Mahesh, J. Liu, R. D. J. Oliver, J. Lim, L. Aspitarte, K. Sharma, P. K. Madhu, A. B. Morales-Vilches, P. K. Nayak, S. Bai, F. Gao, C. R. M. Grovenor, M. B. Johnston, J. G. Labram, J. R. Durrant, J. M. Ball, B. Wenger, B. Stannowski, H. J. Snaith, A piperidinium salt stabilizes efficient metal-halide perovskite solar cells. Science 369, 96-102 (2020).
S. Yang, S. Chen, E. Mosconi, Y. Fang, X. Xiao, C. Wang, Y. Zhou, Z. Yu, J. Zhao, Y. Gao, F. De Angelis, J. Huang, Stabilizing halide perovskite surfaces for solar cell operation with wide-bandgap lead oxysalts. Science 365, 473-478 (2019).
X. Zheng, Y. Hou, C. Bao, J. Yin, F. Yuan, Z. Huang, K. Song, J. Liu, J. Troughton, N. Gasparini, C. Zhou, Y. Lin, D.-J. Xue, B. Chen, A. K. Johnston, N. Wei, M. N. Hedhili, M. Wei, A. Y. Alsalloum, P. Maity, B. Turedi, C. Yang, D. Baran, T. D. Anthopoulos, Y. Han, Z.-H. Lu, O. F. Mohammed, F. Gao, E. H. Sargent, O. M. Bakr, Managing grains and interfaces via ligand anchoring enables 22.3%-efficiency inverted perovskite solar cells. Nat. Energy 5, eabe8130 (2020).

What is claimed is:

1. A perovskite system comprising:
a perovskite film comprising perovskites having a three-dimensional heterostructure ABX₃ being characterized by a tetragonal perovskite surface,
wherein A comprises at least one of methylammonium (MA), formamidinium (FA), cesium (Cs) and guanidium (GUA),
wherein B is Pb or Sn, and
wherein X comprises at least one of I, Br or Cl; and
an interfacial capping layer comprising surface-capping ligands being anilinium (An)-based ligands, wherein the surface-capping ligands are distributed at the tetragonal perovskite surface of the perovskite film and are non-reactive with the perovskites, as measured by time-of-flight secondary ion mass spectrometry (TOF-SIMS).

2. The system of claim 1, wherein A consists of MA.

3. The system of claim 2, wherein ABX₃ is MAPbI₃.

4. The system of claim 1, wherein A has the formula CsxMAyFAi−x−y, wherein x is in a range from 0<x<1, wherein y is in a range from 0<y<1, wherein i is in a range from 0<i<1, and wherein x+y<1.

5. The system of claim 4, wherein ABX₃ is CS_{0.05}MA_{0.05}FA_{0.9}Pb(I_{0.95}Br_{0.05})₃ or Cs_{0.05}MA_{0.15}FA_{0.8}PbI₃.

6. (canceled)

7. (canceled)

8. The system of claim 1, wherein the An-based ligand is anilinium or an alkyl anilinium.

9. The system of claim 8, wherein the An-based ligand is tert-butyl-substituted 3,5-di-tert-butylanilinium, 3-tert-butylanilinium, 4-tert-butylanilinium, or any mixture thereof.

10. The system of claim 1, wherein the surface-capping ligand is a surface-passivating ligand being a fluorinated anilinium ligand, thereby forming the interfacial capping layer being an interfacial passivating layer.

11. The system of claim 10, wherein the fluorinated anilinium ligand is 2-fluoroanilinium (2FAn), 3-fluoroanilinium (3FAn), 4-fluoroanilinium (4FAn), 2,6-difluoroanilinium (26FAn), 3,4,5-trifluoroanilinium (345FAn), 2,3,4,5,6-pentafluoroanilinium (23456FAn), or any mixture thereof.

12. The system of claim 1, wherein a C—N/FA N ratio of the anilinium-based ligand in the perovskite solar cell system is of at most 0.1, optionally of at most 0.05, measured by angle-resolved x-ray photoelectron spectroscopy (AR-XPS).

13. The system of claim 1, wherein the An-based ligand has a steric effect index (STEI) is at least 2, at least 2.1, at least 2.2, at least 2.3 or at least 2.4 as calculated by density-functional theory (DFT) calculations.

14. The system of claim 1, wherein the An-based ligand has a solubility in isopropanol between 0.5 and 5 mg m⁻¹, as determined by standard gravimetric analysis.

15. The system of claim 1, wherein the interfacial passivating layer has a thickness of at most 10 nm as measured by TOF-SIMS.

16. A solar cell or module comprising a perovskite system as defined in claim 1.

17. The solar cell or module of claim 16, further comprising at least one of:
a hole transport layer onto which the perovskite film is deposited, the hole-transport layer being a self-assembled monolayer 2PACz, 2PACz derivatives, a polymeric hole conductor poly(triaryl amine) (PTAA), poly(3,4-ethylenedioxythiophene) polystyrene sulfonate (PEDOT), or a p-type inorganic semiconductor, optionally being nickel oxide (NiOₓ);
a substrate onto which the hole-transport layer is deposited, the substrate being Fluorine-doped Tin Oxide (FTO) glass or an Indium Tin Oxide (ITO) glass; and
an electron transport layer being deposited on the perovskite system, the electron transport layer being thermally evaporated C₆₀/bathocuproine (BCP) bilayer, solution-processed [6,6]-phenyl-C61-butyric acid methyl ester (PCBM)/BCP bilayer, or C₆₀/ALD-SnO₂ bilayer.

18. (canceled)

19. (canceled)

20. A method for preparing a perovskite system as defined in claim 1, the method comprising:
providing a solution comprising the anilinium-based ligand and a solvent;
coating the perovskite film with the solution during a processing time of at least 5 seconds for distributing the anilinium-based ligands onto the tetragonal perovskite surface and produce a surface-treated perovskite film; and
annealing the surface-treated perovskite film to form the perovskite system.

21. The method of claim 20, wherein the processing time is between 5 seconds and 30 seconds.

22. The method of claim 20, wherein the solvent is isopropanol, chlorobenzene, chloroform, toluene, or any mixtures thereof.

23. The method of claim 20, wherein the solution has a concentration in the anilinium-based ligand between 0.2 and 2 mg/mL.

24. The method of claim 20, wherein the coating is performed by spin-coating, blade-coating, or slot-die coating.

25. The method of claim 20, wherein the annealing is performed at a temperature between 60° C. and 120° C. for a second processing time between 1 min and 10 min.
